(19) United States
(12) Patent Application Publication
(10) Pub. No.: US 2023/0318253 A1
(43) Pub. Date: Oct. 5, 2023

(54) ULTRA-HIGH STABILITY BRILLOUIN LASER

(71) Applicant: IMRA America, Inc., Ann Arbor, MI (US)

(72) Inventors: Martin E. Fermann, Dexter, MI (US); Antoine Jean Gilbert Rolland, Longmont, CO (US); Peng Li, Ann Arbor, MI (US)

(21) Appl. No.: 18/177,410

(22) Filed: Mar. 2, 2023

Related U.S. Application Data
(60) Provisional application No. 63/269,029, filed on Mar. 8, 2022.

(51) Int. Cl. H01S 3/30; H01S 3/13; H01S 3/0941; H01S 3/094; H01S 3/10; H01S 3/00; H01S 3/08

(52) U.S. Cl. CPC H01S 3/302; H01S 3/0085; H01S 3/08013; H01S 3/094076; H01S 3/0941; H01S 3/10092; H01S 3/1305

(57) ABSTRACT

Example ultra narrow linewidth Brillouin lasers are disclosed that are pumped by pump lasers that are controlled via optimal control schemes in order to stabilize the Brillouin laser output frequency and minimize the Brillouin output linewidth. The control schemes are based on feedback loops to match the pump laser frequency to the optimum Stokes shift on the one hand and to line-narrow the pump laser linewidth on the other hand via comparing the linewidth of the pump laser with the linewidth of the Brillouin laser. The feedback loops in the control schemes can be partially or fully replaced with feedforward control schemes, allowing for larger bandwidth control. Provision for simultaneous oscillation of the Brillouin lasers on two polarization modes allows for further line-narrowing of the Brillouin output. The ultra-narrow linewidth Brillouin lasers can be advantageously implemented as pumps for microresonator based frequency combs, and can also be integrated to the chip scale and be constructed with minimal vibration sensitivity. The ultra-narrow linewidth Brillouin lasers can be widely tuned and a frequency readout can be provided via the use of a frequency comb. When phase locking a frequency comb to the Brillouin laser, ultra-stable microwave generation can be facilitated.

### CLAIM OF PRIORITY

This application claims the benefit of priority to U.S. Provisional Appl. No. 63/269,029 filed on Mar. 8, 2022 and incorporated in its entirety by reference herein.

### BACKGROUND

### Field

The present application relates generally to ultra-high stability Brillouin lasers.

### Description of the Related Art

Ultra-high stability continuous wave (cw) lasers provide single frequency light output with a very narrow spectral linewidth, which in some cases can reach the Hz and even sub-Hz level. Such lasers are of great interest for many applications, comprising sensing, metrology, microwave generation, communications and quantum computing. For example, in quantum computing, the provision of a very stable frequency reference can be used to improve the fidelity of qubits of quantum computers based on atomic or ionic transitions, which in turn allows a maximization of the number of quantum gate manipulations that can be performed on those transitions.

Ultra-high stability cw lasers can for example be based on Brillouin fiber lasers, resonantly pumped by a cw laser (see, e.g., U.S. Pat. Appl. Publ. No. 2018/0180655). Other resonant pumping schemes have also been disclosed (see, e.g., U.S. Pat. Nos. 10,566,759; 11,050,214).

### SUMMARY

In certain implementations, a fiber Brillouin laser system is configured using singly resonant operation, comprising non-resonant pumping and a resonant Brillouin lasing output. Mode hops in the Brillouin laser can be avoided by having a pump laser frequency that is offset from the Brillouin laser frequency by the Brillouin frequency shift via a proportional integrated differential (PID) feedback loop. The PID feedback loop can measure the difference between the pump laser and Brillouin laser frequencies and can compare the difference to a reference oscillator providing a microwave frequency corresponding to the Brillouin frequency shift. A second PID loop can optionally further reduce the linewidth of the pump laser by comparing the linewidth of the Brillouin laser with the linewidth of the pump laser.

In certain implementations, feedback based pump laser modulation schemes can be augmented by feedforward pump laser modulation schemes which can line-narrow the Brillouin laser pump, while the feedback mechanism can ensure that the pump laser frequency is offset from the Brillouin laser frequency by the Brillouin frequency shift.

In certain implementations, feedforward pump laser modulation schemes can line-narrow the Brillouin laser pump, while at the same time ensuring that the pump laser frequency is offset from the Brillouin laser frequency by the Brillouin frequency shift.

In certain implementations, two pump lasers can be used to excite two Brillouin oscillations on orthogonal polarizations in a Brillouin fiber cavity. By interference of the two polarizations a beat frequency can be obtained, which is a measure of the average temperature of the Brillouin cavity. Control of the beat frequency can further be implemented to further reduce the linewidth of the Brillouin laser.

In certain implementations, self-injection locking of two pump lasers to the two orthogonal polarization modes of a Brillouin fiber cavity can be used to minimize the complexity of an ultra-narrow linewidth Brillouin fiber laser.

In certain implementations, feedback and feedforward pump modulation schemes can be used for two pump lasers along with optimized excitation of the two orthogonal polarization modes of a Brillouin fiber cavity and stabilization of the polarization beat frequency to further reduce the linewidth of the Brillouin laser.

In certain implementations, an ultra-narrow linewidth Brillouin fiber laser can be used as a pump source for a microresonator, facilitating the generation of a frequency comb with GHz level frequency spacing with ultra-low noise.

In certain implementations, a chip scale ultra-narrow linewidth Brillouin fiber laser can be constructed in conjunction with self-injection, feedback, and feedforward control.

In certain implementations, an ultra-narrow linewidth Brillouin fiber laser can be used in conjunction with a frequency comb for the determination of the absolute frequency of the cw laser frequency or to produce a low-noise microwave frequency signal.

In certain implementations, an ultra-narrow linewidth Brillouin fiber laser can be tuned over a broad spectral range without mode hops.

In certain implementations, an ultra-narrow linewidth Brillouin fiber laser can be widely tuned while the output frequency is determined with a frequency comb.

In certain implementations, an ultra-narrow linewidth Brillouin fiber laser can be constructed with reduced vibration sensitivity.

### BRIEF DESCRIPTION OF THE DRAWINGS

FIG. 1A schematically illustrates an example narrow linewidth Brillouin fiber laser in accordance with certain implementations described herein.

FIG. 1B schematically illustrates an alternative example narrow linewidth Brillouin fiber laser in accordance with certain implementations described herein.

FIG. 1C schematically illustrates yet another alternative example narrow linewidth Brillouin fiber laser in accordance with certain implementations described herein.

FIG. 2 illustrates a measurement of the frequency stability of a Brillouin fiber laser mounted in air and in vacuum.

FIG. 3A schematically illustrates an example of simultaneous operation of two narrow linewidth Brillouin fiber lasers on two different polarizations in accordance with certain implementations described herein.

FIG. 3B schematically illustrates an example of simultaneous operation of two narrow linewidth Brillouin fiber lasers on two different polarizations based on self-injection locking in accordance with certain implementations described herein.

FIG. 3C schematically illustrates an example of simultaneous operation of two narrow linewidth Brillouin fiber lasers on two different polarizations using feedforward locking schemes.

FIG. 4 schematically illustrates an example ultra-narrow linewidth Brillouin fiber laser used as a pump source for a frequency comb based on a microcomb resonator in accordance with certain implementations described herein.

FIG. 5A schematically illustrates an example ultra-narrow linewidth chip scale Brillouin laser with self-injection in accordance with certain implementations described herein.

FIG. 5B schematically illustrates an example ultra-narrow linewidth chip scale Brillouin laser with feedforward locking in accordance with certain implementations described herein.

FIG. 6 schematically illustrates an example ultra-narrow linewidth Brillouin fiber laser referenced to a frequency comb for absolute frequency determination in accordance with certain implementations described herein.

FIG. 7 schematically illustrates an example wavelength tunable ultra-narrow linewidth Brillouin fiber laser in accordance with certain implementations described herein.

FIG. 8 schematically illustrates an example fiber Brillouin cavity with reduced vibration sensitivity in accordance with certain implementations described herein.

FIG. 9 schematically illustrates an example narrow linewidth Brillouin fiber laser with self-injection in accordance with certain implementations described herein.

FIG. 10 schematically illustrates an example dual polarization narrow linewidth Brillouin fiber laser with self-injection in accordance with certain implementations described herein.

FIG. 11 schematically illustrates an example dual polarization narrow linewidth Brillouin fiber laser with self-injection in accordance with certain implementations described herein.

FIG. 12 schematically illustrates an example dual polarization narrow linewidth Brillouin fiber laser comprising only one pump laser with self-injection in accordance with certain implementations described herein.

FIG. 13A illustrates an example frequency noise measurement of the polarization beat frequency as a function of side-band frequency of a dual polarization Brillouin fiber laser in accordance with certain implementations described herein.

FIG. 13B illustrates an example Allan deviation measurement of the polarization beat frequency as a function of side-band frequency of a dual polarization Brillouin fiber laser in accordance with certain implementations described herein.

FIG. 14 illustrates an example measurement of thermal tuning of the output frequency of a Brillouin fiber laser in accordance with certain implementations described herein.

FIG. 15A schematically illustrates an example three frequency output, dual polarization narrow linewidth Brillouin laser with self-injection in accordance with certain implementations described herein.

FIG. 15B schematically illustrates an example dual frequency output, narrow linewidth Brillouin fiber laser with self-injection in accordance with certain implementations described herein.

FIG. 16A schematically illustrates an example ultra-narrow linewidth Brillouin fiber laser referenced to a frequency comb for short and long-term frequency stabilization of the Brillouin laser output frequency in accordance with certain implementations described herein.

FIG. 16B schematically illustrates an example dual frequency ultra-narrow linewidth Brillouin fiber laser referenced to a frequency comb for short and long-term frequency stabilization of the difference frequency between the Brillouin laser outputs in accordance with certain implementations described herein.

FIG. 17A schematically illustrates an example ultra-narrow linewidth Brillouin fiber laser with self-injection with an ultra-long cavity length in accordance with certain implementations described herein.

FIG. 17B schematically illustrates an example of representative frequency nodes along two polarizations of an ultra-narrow linewidth Brillouin fiber laser with an ultra-long cavity length in accordance with certain implementations described herein.

FIG. 18 schematically illustrates an example ultra-narrow linewidth Brillouin laser based on frequency locking to the two polarizations of a long fiber delay line in accordance with certain implementations described herein.

The figures depict various implementations of the present disclosure for purposes of illustration and are not intended to be limiting. Wherever practicable, similar or like reference numbers or reference labels may be used in the figures and may indicate similar or like functionality.

### DETAILED DESCRIPTION

Certain implementations described herein advantageously provide compact and highly robust ultra-narrow linewidth Brillouin fiber laser systems that can further technological developments in quantum computers, precision frequency metrology, communications, microwave technology, sensing and other applications.

Certain implementations described herein advantageously provide compact, high stability Brillouin fiber laser sources based on proportional integrated differential (PID) feedback loops for pump laser control to reduce (e.g., minimize) the Brillouin laser linewidth.

Certain implementations described herein advantageously provide compact, high stability Brillouin fiber laser sources using feedback along with feedforward pump laser control.

Certain implementations described herein advantageously provide compact, high stability Brillouin fiber laser sources with feedforward pump laser control for locking the pump laser frequency to the peak gain of the Brillouin cavity and for line narrowing of the pump laser.

Certain implementations described herein advantageously provide compact, high stability Brillouin fiber laser sources based on simultaneous Brillouin oscillation on the two orthogonal polarization directions of a Brillouin fiber laser cavity.

Certain implementations described herein advantageously provide compact, high stability Brillouin fiber laser sources based on simultaneous Brillouin oscillation on the two orthogonal polarization directions of a Brillouin fiber laser cavity while frequency narrowing the Brillouin pump lasers via self-injection.

Certain implementations described herein advantageously provide compact, high stability Brillouin fiber laser sources based on simultaneous Brillouin oscillation on the two orthogonal polarization directions of a Brillouin fiber laser cavity while frequency narrowing the Brillouin pump lasers via feed forward schemes.

Certain implementations described herein advantageously use an ultra high stability Brillouin fiber laser as a pump source for a microresonator based frequency comb.

Certain implementations described herein advantageously provide an ultra high stability chip scale Brillouin laser.

Certain implementations described herein advantageously provide an ultra high stability Brillouin fiber laser with an absolute frequency reading.

Certain implementations described herein advantageously provide an ultra high stability Brillouin fiber laser in conjunction with a frequency comb for low noise microwave generation.

Certain implementations described herein advantageously provide an ultra high stability Brillouin fiber laser which is tunable over a wide spectral range.

Certain implementations described herein advantageously provide an ultra-narrow linewidth Brillouin fiber laser which can be widely tuned while the output frequency is determined with a frequency comb.

Certain implementations described herein advantageously provide an ultra high stability Brillouin fiber laser with reduced vibration sensitivity.

### Overview

Ultra high stability Brillouin fiber lasers have been subject of many investigations. Indeed, it has long been known that Brillouin fiber lasers can in principle achieve sub-Hz linewidths (P.T. Callahan et al., “Frequency-Independent Phase Noise in a Dual-Wavelength Brillouin Fiber Laser,” IEEE J. Quantum Elec., vol. 47, pp. 1142 - 1150 (2011)) and may potentially rival if not outperform the performance of traditional ultra-narrow linewidth lasers referenced to precision bulk reference cavities. With the help of bulk reference cavities, a frequency stability of 1 ×10⁻¹⁵ in 1 sec and better can be routinely generated, as for example described in Ludlow et al., “Compact, thermal-noise-limited optical cavity for diode laser stabilization at 1×10⁻ ¹⁵,” Opt. Lett. Vol. 32, pp. 641 - 643 (2007).

However, to date the stability achieved with Brillouin fiber lasers has been orders of magnitude worse than theoretically possible. Danion et al. has a reported a Brillouin laser line width < 50 Hz (see Danion et al., “Mode-hopping suppression in long Brillouin fiber laser with non-resonant pumping,” Opt. Lett. Vol. 41, pp. 2362 - 2365 (2016). In a more recent demonstration (see, U.S. Pat. No. 11,050,214), a Brillouin fiber laser with a linewidth of ≈20 Hz was demonstrated, however, the system relied on resonant pumping and rather complex phase locking electronics, as well as the use of narrow linewidth pump sources, which increases the cost of such devices and limits their utilization. A narrow Brillouin linewidth was also recently demonstrated (see U.S. Pat. No. 10,566,759), based on self-injection locking of the Brillouin pump laser.

To date, no Brillouin fiber laser has been demonstrated that combines ultra-narrow linewidth operation with low cost cw pump lasers and robust control electronics. Examples of Ultra-low noise Brillouin fiber laser

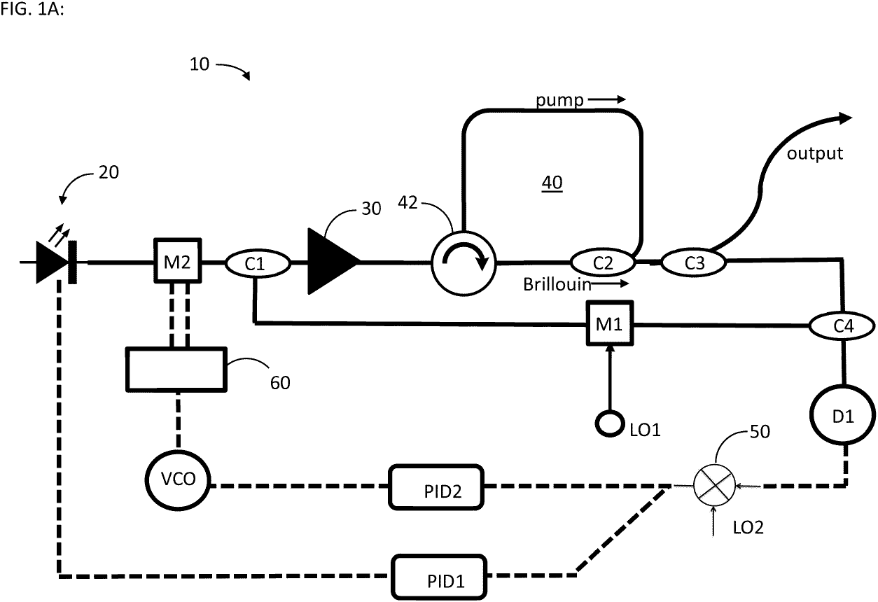

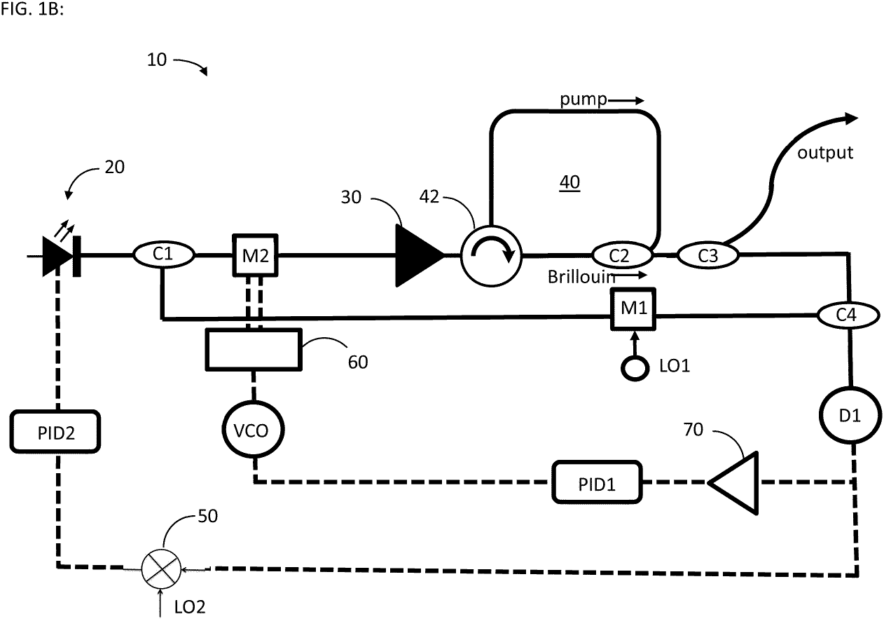

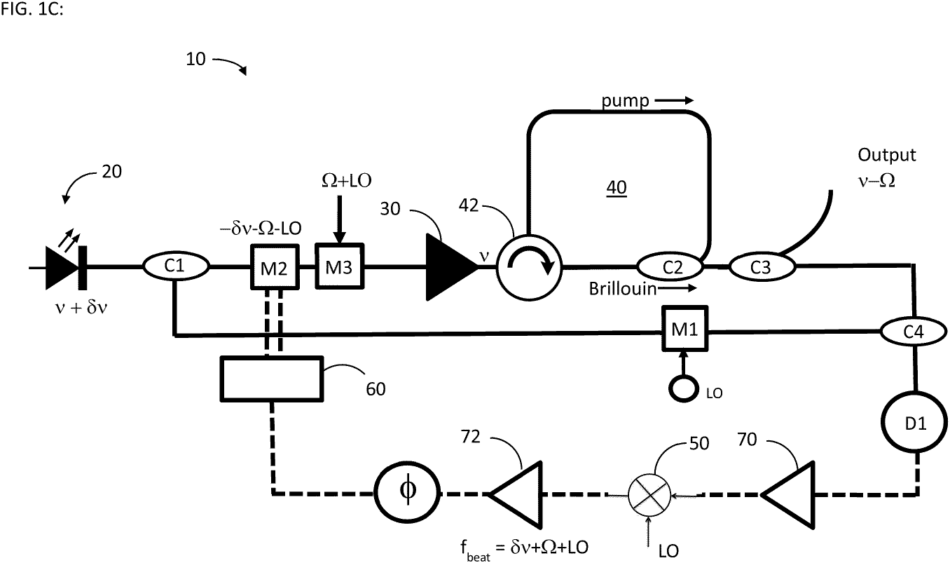

Certain implementations disclosed herein provide a simplified scheme for an ultra-low-noise Brillouin fiber laser. FIG. 1A schematically illustrates an example ultra-low-noise Brillouin laser 10 (e.g., Brillouin fiber laser) in accordance with certain implementations described herein. As described herein, the ultra-low-noise Brillouin laser 10 comprises a single frequency pump laser 20 (e.g., laser diode with a laser linewidth of the order of 10 kHz - 1 MHz), which can be conditioned via feedback loops to optimize the stability of the Brillouin laser and minimize its linewidth. The output of the pump laser 20 can be amplified with a fiber amplifier 30 and directed via coupler C1 (for example with a splitting ratio of 80/20), which can direct around 80% of the pump light into a nonlinear cavity 40 (e.g., also referred to herein as a Brillouin cavity 40 or a Brillouin fiber cavity 40) via an optical circulator 42. In an example implementation, all the fiber of the Brillouin fiber cavity 40 can be polarization maintaining, the pump laser 20 can emit 1 - 10 mW of light at 1560 nm, the fiber amplifier 30 can amplify the laser signal to a level of 100 - 200 mW and the Brillouin fiber cavity 40 can comprise around 10 - 100 m of standard single mode polarization maintaining fiber. The pump laser 20 can have a linewidth in the 100 Hz - 1 MHz range. Other values are also compatible with certain implementations described herein.

Coupler C2 can be used to, for example, couple 10% of the Brillouin signal output out of the Brillouin cavity 40. The output from the Brillouin laser 10 can be extracted via coupler C3 (for example, with a 50/50 splitting ratio). The second output from C1 can be directed to an electro-optic modulator M1, which can compensate for most of the Stokes shift of the Brillouin laser output (the Stokes shift that produces the maximum gain for the wavelength, temperature, and fiber material being used is referred to herein as the optimum Stokes shift; for example, at a wavelength of 1560 nm at room temperature in standard silica fiber, the Stokes shift that produces the maximum gain, and hence the optimum Stokes shift, is ≈ -10.9 GHz) via the application of a modulation signal of, for example, 10.8 GHz from a local oscillator LO1. The output from M1 can be directed to the two input leads of coupler C4, which can combine the frequency down-shifted output from the Brillouin laser 10 with a fraction of the pump light. The interference or beat signal between these two signals can be measured at detector D1. The resulting electrical beat signal can be mixed with a local oscillator reference LO2 at, for example, 100 MHz via, for example, a dual balanced mixer 50, which measures the frequency difference between the Brillouin laser output signal and the peak gain frequency of the Brillouin laser 10. The local oscillator reference frequency can be in the range from 100 MHz to around 10 GHz, other frequencies are also compatible with certain implementations described herein. Generally, the frequency relation between LO1 and LO2 can be selected as LO1 ± LO2 ≈ 10.9 GHz.

The output from the mixer 50 can be split in two and directed to two laser controllers (e.g., PID controllers, PID1 and PID2). PID1 can generate an error signal that can control the frequency of the pump laser 20 such that the Brillouin laser 10 emits at the optimum Stokes shift. While not shown in FIG. 1A, the pump laser 20 can comprise at least one actuator configured to frequency modulate the pump laser 20. Actuators for pump laser frequency control compatible with certain implementations described herein include but are not limited to diode temperature controllers or piezo-electric transducers (PZTs) that are typically included in commercial semiconductors lasers.

PID2 generates an error signal that controls a voltage controlled oscillator VCO, which, via modulator M2, can line narrow the linewidth of the pump laser 20 to the linewidth of the Brillouin laser 10. Modulator M2 can comprise an acousto-optic modulator AOM or an electro-optic modulator EOM in certain implementations. Single-sideband EOMs or dual parallel Mach-Zehnder modulators, can be used in certain other implementations. Single-sideband EOMs are typically based on dual-parallel Mach-Zehnder modulators. Such modulators can comprise two Mach-Zehnder modulators nested within a third Mach-Zehnder modulator. Two microwave signals with an adjustable phase delay can then be applied to the two nested Mach-Zehnder modulators. To obtain single-sideband modulation, an additional three controllable bias voltages can be provided that control the phase bias of the three Mach-Zehnder modulators. For example, as shown in FIG. 1A, the Brillouin laser 10 can comprise a control box 60 configured to receive the signal from the VCO and to drive a dual parallel Mach-Zehnder modulator by providing the three controllable bias voltages and the two microwave signals. For simplicity, FIG. 1A only shows the two microwave signals applied to the single-sideband modulator derived from the control box 60. In certain implementations, the control box 60 can also include temperature control to stabilize the three optical phase biases. The control loop can produce a frequency offset for the pump laser 20, that can be compensated or stabilized by modulator M2. In certain implementations, PID1 is relatively slow with a feedback bandwidth in the range from 10 Hz - 10 kHz and PID2 is relatively fast with a PID feedback bandwidth in the range from 1 kHz - 10 MHz. The Brillouin cavity 40 can further be within a vacuum chamber to reduce acoustic and thermal noise and can be provided with precision temperature control to further reduce thermal noise of the Brillouin laser 10. In certain implementations, the pump laser 20 itself can comprise slow and fast actuators, such that a separate modulator (M2) can be omitted and the two PID error signals can be directly applied to the pump laser 20. Such an implementation is not separately shown. As used herein, the term “actuators” has its broadest reasonable interpretation, including but not limited to actuators that control the pump laser diode frequency, either inside the pump laser 20 (e.g., pump laser diode) or external to the pump laser 20 (e.g., pump laser diode).

Certain implementation described herein also benefit from using a feedback scheme in conjunction with a feedforward scheme for locking the pump laser 20 to the peak of the Brillouin gain and for line-narrowing of the pump laser 20. FIG. 1B schematically illustrates an example Brillouin laser 10 (e.g., Brillouin fiber laser) in accordance with certain such implementations. In FIG. 1B, detector D1 measures the beat signal between the frequency-down-converted pump light and the output of the Brillouin laser 10. Modulator M1 is used for frequency down-conversion, as described herein with respect to FIG. 1A. A fraction of the pump light is extracted via coupler C1, located upstream of modulator M2, in contrast to the example Brillouin laser 10 shown in FIG. 1A, where coupler C1 is located downstream of modulator M2. The other part of the pump light is amplified by an optical amplifier 30 and injected into the Brillouin cavity 40. The beat signal generated by detector D1 can be split in two. The first part of the beat signal can be amplified via an RF amplifier 70 and directed via a first PID (PID1) to generate an error signal for line-narrowing of the pump laser 20 to the linewidth of the Brillouin laser 10. The error signal can be directed to a VCO, which controls modulator M2. M2 can comprise an AOM or an EOM and a control box 60 can be between VCO and M2. The second part of the beat signal can be directed via a mixer 50 to a second PID (PID2) to lock the pump laser 20 such that the Brillouin laser 10 emits at the optimum Stokes shift. This control loop operates similarly to the control loop (with PID1) as disclosed with respect to FIG. 1A. The control loop produces a frequency offset for the pump laser 20 which can be compensated or stabilized by modulator M2.

Certain implementation described herein also benefit from using only a feedforward scheme for locking the pump laser 20 such that the Brillouin laser 10 emits at the optimum Stokes shift and for line-narrowing of the pump laser 20. FIG. 1C schematically illustrates another example Brillouin laser 10 in accordance with certain such implementations. Feedforward schemes can produce the highest control bandwidth and can be used with a pump laser 20 (e.g., pump laser diode) with linewidths up to 1 MHz and more. Specifically, modulator M2 can compensate for the noise of the pump laser 20 and can apply a frequency offset to the pump laser 20. Modulator M3 can compensate for this frequency offset. There are at least two options for application of a LO signal. In option 1, the LO signal can be applied via modulator M1 in the optical domain. In option 2, the LO can be applied in the RF domain via a mixer 50. Detector D1 can measure the beat signal between the Brillouin cavity output and the noisy pump laser 20, optionally frequency-down-converted in the optical domain by a LO (in option 1) and can generate an error signal. The error signal can be down-converted by a LO in the RF domain (in option 2) by directing the output of detector D1 (e.g., via an RF amplifier 70, mixer 50, RF amplifier 72, and phase shifter Φ, as shown in FIG. 1C) to an appropriate modulator, such as a dual parallel Mach Zehnder modulator. Frequency deviations of the pump laser 20 from the peak gain of the Brillouin cavity 40, and line narrowing of the pump laser 20 to the linewidth of the Brillouin laser output can be simultaneously provided. A LO for frequency shifting in the optical domain can be combined with an LO for frequency down-conversion in the RF domain. Such an implementation is not separately shown.

It is instructive to keep track of the various signals in this locking scheme. Referring to FIG. 1C which schematically illustrates an example implementation, the pump laser frequency can be v + δν, where δv is representative of the frequency noise of the pump laser 20, the Brillouin shift can be Ω, the output frequency from the Brillouin cavity 40 can be f_{Br} and a local oscillator frequency can be LO. The modulation signal applied to modulator M2 can then be expressed as: M2 = -δν - Ω - LO and the modulation signal applied to modulator M3 can then be expressed as: M3 = Ω + LO. The frequency fᵢₙ injected to the Brillouin cavity 40 can then be expressed as fᵢₙ = v, and the output frequency from the Brillouin cavity 40 can be expressed as f_{Br} = v - Ω. Detector D1 detects the beat signal f_{beat}, which accounting for the LO (in option 1 or 2) can be transformed to f_{beat} = (v + δν) - (v - Ω) + LO = δv + Ω + LO, producing a modulation signal M2 = -δν -Ω - LO for a self-consistent solution. In certain implementations, the local oscillator can be omitted, but then M2 and M3 can be subject to a high modulation frequency (e.g., around 10.9 GHz), and precise phase control between M2 and M3 can be used to avoid introduction of noise. The local oscillator frequency can be selected in the range from 0 to Ω. However, for modulators that utilize a minimal offset frequency, the maximum LO frequency can be a few MHz lower than Ω. This feedforward scheme suppresses the diode laser pump noise via using the Brillouin cavity 40 as a reference and can produce a low noise input to the Brillouin cavity 40. Other configurations are also compatible with certain implementations described herein.

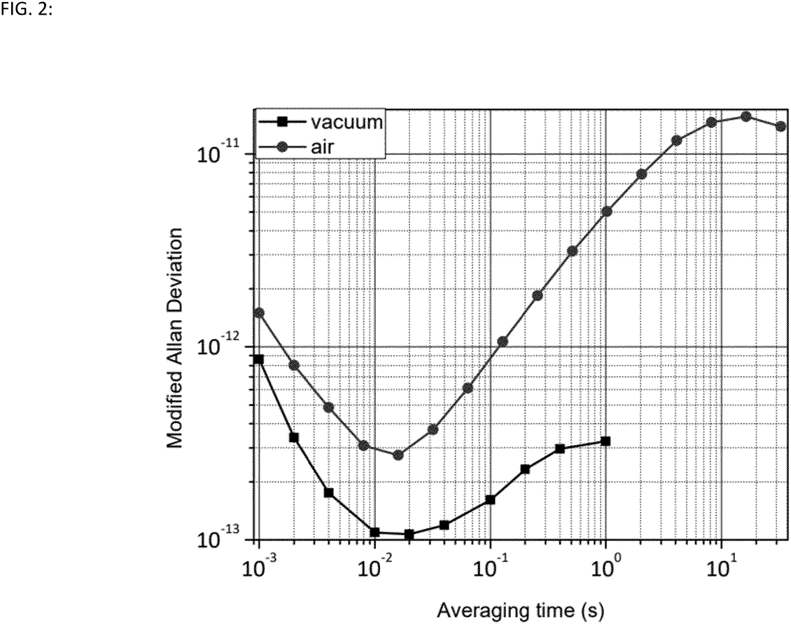

An example of the measured frequency stability of a Brillouin laser 10 comprising a Brillouin cavity 40 with a 75 m fiber Brillouin cavity length as constructed according to FIG. 1A (but with modulator M2 omitted) is shown in FIG. 2. With precision temperature control of the Brillouin cavity 40 to within 10 mK and with the Brillouin cavity 40 enclosed in a vacuum chamber, a frequency stability of 10⁻¹³ was measured after around 200 ms. In contrast, the frequency stability of the Brillouin laser 10 mounted in air was around 5 times worse.

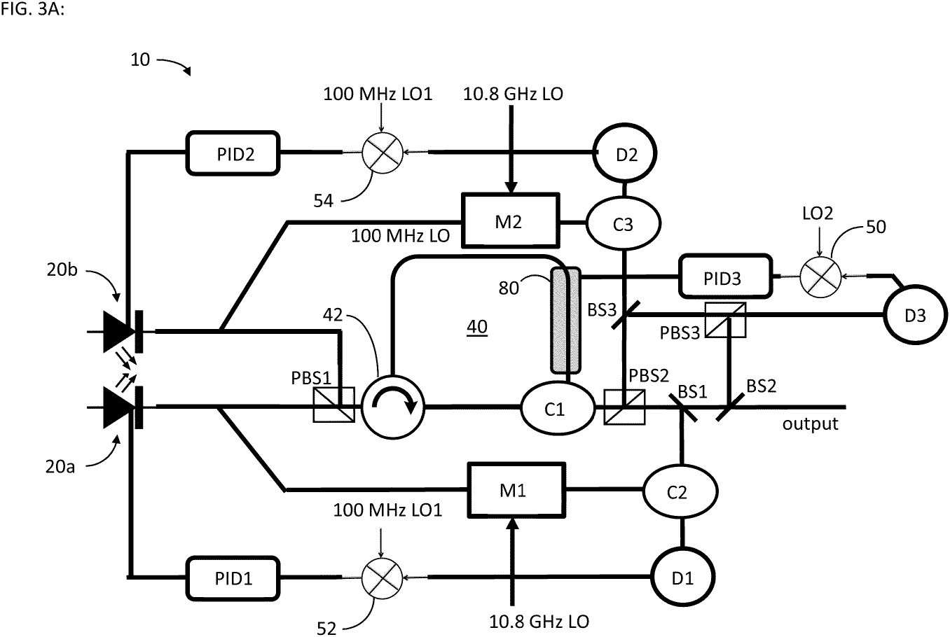

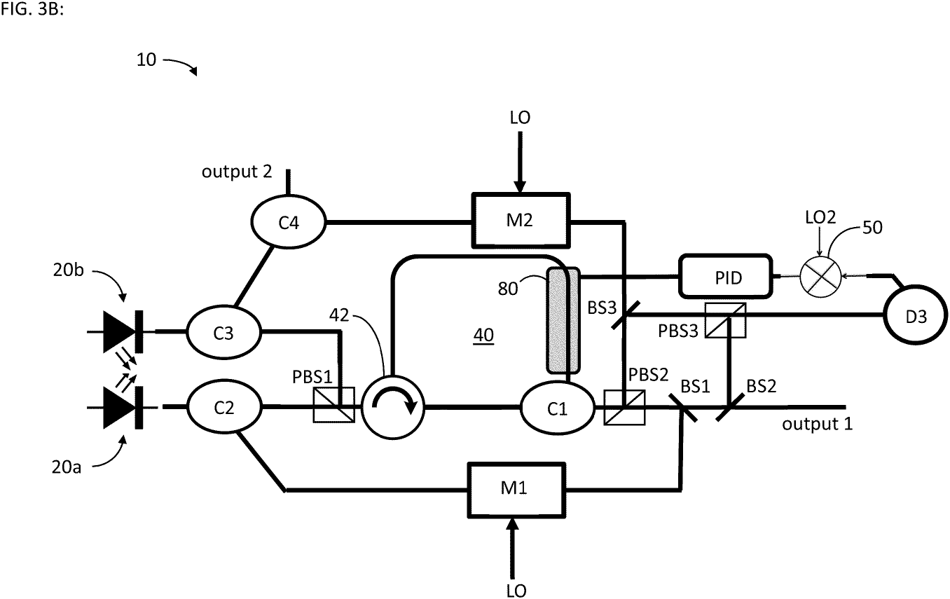

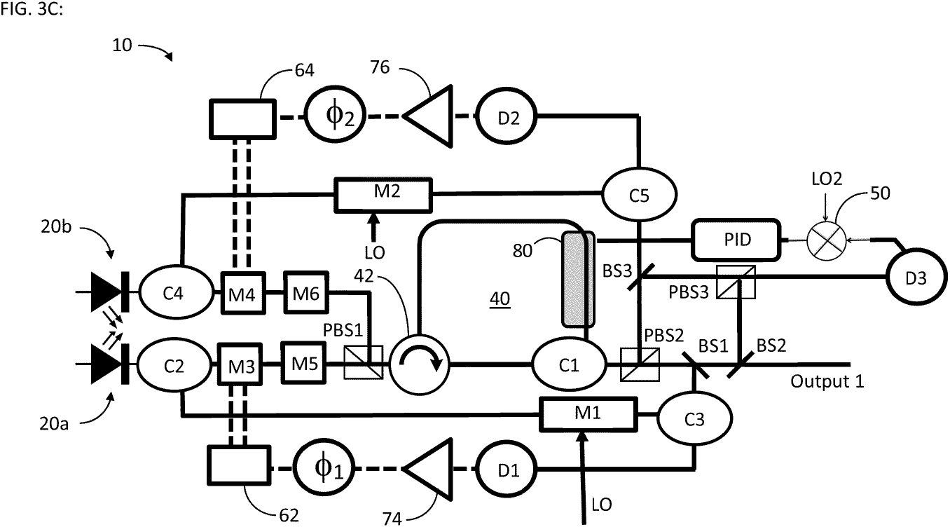

In certain implementations, the two orthogonal polarization modes in a fiber Brillouin cavity 40 can be pumped by two different lasers and the temperature of the Brillouin cavity 40 can be stabilized via controlling the beat frequency between the polarization modes. FIG. 3A schematically illustrates an example Brillouin laser 10 in accordance with certain such implementations. A first pump laser 20a provides the pump light for Brillouin oscillation on the first of the two polarization eigenmodes of the Brillouin cavity 40. The components connected with the first pump laser 20a serve the same function as described herein with respect to FIG. 1A. However, for simplicity, FIG. 3A shows only one PID loop (PID1) which can lock the pump laser frequency such that the Brillouin laser 10 emits at the optimum Stokes shift and can also line-narrow the first pump laser 20a, where line-narrowing can be via a general actuator (e.g., a fast actuator within the pump diode or an external modulator; not shown). A second pump laser 20b similarly provides the pump light for Brillouin oscillation on the second of the two polarization eigenmodes of the Brillouin cavity 40. The components connected with the second pump laser 20b serve the same function as described herein with respect to FIG. 1A. However, for simplicity again, FIG. 3A shows only one PID loop (PID2) which can lock the second pump laser 20b such that the Brillouin laser 10 emits at the optimum Stokes shift and can also line-narrow the second pump laser 20b. The two pump lasers 20a,b can be coupled into the Brillouin cavity 40 via a circulator 42 and polarization beam splitter PBS1, which can be aligned with the two polarization axes of the Brillouin cavity 40. The output from the Brillouin cavity 40 can be extracted via coupler C1 and PBS2, which can separate the two oscillating polarization modes from the Brillouin cavity 40.

In order to observe a beat signal between the two oscillating polarization modes, a fraction of the output along the two polarization modes can be diverted via the beam splitters BS1, BS2 and BS3 and directed to polarization beam splitter PBS3, where the two signals along the two polarization modes can be combined and subsequently received via detector D3. The polarization beat frequency can be in the MHz range and can be phase locked to an external reference frequency LO2 via a mixer 50a and a third PID controller (PID3), which can be configured to generate a control signal for a heater 80 (e.g., fiber heating element) in thermal communication with (e.g., inside) at least a portion of the Brillouin cavity 40. The heater feedback loop can be slower and configured not to interfere with the PID loops implemented for frequency stabilization and line narrowing of the pump lasers 20a,b. The narrow linewidth output can, for example, be extracted via BS2. Beam splitters BS1 and BS3 can direct the two polarization modes to detectors D1 and D2 respectively, where a beat signal between the respective frequency-down-shifted diode pumps and the respective Brillouin signals can be observed and locked to local oscillator reference frequencies via the PID loops PID1 and PID2 (e.g., each comprising a corresponding mixer 52, 54 as shown in FIG. 3A), controlling the diode pump frequencies.

In certain implementations the two orthogonal polarization modes in a Brillouin cavity 40 can be excited with two pump lasers 20a,b (e.g., two pump laser diodes) self-injection locked to those two polarization modes. FIG. 3B schematically illustrates an example Brillouin laser 10 in accordance with certain such implementations. In FIG. 3B, as in FIG. 3A, PBS1 can combine the two polarization states from the two diode pump lasers 20a,b before injection into the Brillouin cavity 40 along the two polarization axes via the circulator 42. Also, as in FIG. 3A, PBS2 can receive the two polarization states from the Brillouin cavity 40, which can be combined via PBS3 to generate a beat signal in detector D3, which can be used for temperature control of the Brillouin cavity 40 via the PID circuit.

To facilitate injection locking, the two frequency-downshifted polarization outputs of the Brillouin cavity 40 can be directed via PBS2 and BS1 and BS3, respectively, to the EO modulators (e.g., M1 and M2). The downshifted Brillouin outputs can be upshifted by the EO modulators M1, M2 back to approximately the pump diode laser frequencies. The upshifted Brillouin outputs can then be back-injected into the pump lasers 20a,b via couplers C2 and C3, respectively, self-injection-locking the operational frequency of the pump lasers 20a,b to the respective Brillouin resonances. In conjunction with enclosure of the Brillouin cavity 40 into a vacuum chamber, precision temperature control and control of the beat frequency between the two Brillouin polarization modes via the PID loop, frequency stability can be obtained at a level of < 10⁻¹⁴ and even <10⁻¹⁵, resulting in an optical output with a sub Hz linewidth. Moreover, self-injection locking can allow for the use of pump lasers 20a,b comprising relatively low quality pump laser diodes with a linewidth of ≈ 1 MHz, which can be readily line-narrowed to the tens of Hz level or lower by the self-injection process. The line-narrowed output from the Brillouin laser 10 can, for example, be extracted via output 1.

In certain implementations, the two orthogonal polarization modes in a Brillouin cavity 40 can be excited with two pump lasers 20a,b (e.g., pump laser diodes) line narrowed via a combination of a feedback and feedforward scheme or a feedforward scheme as discussed with respect to FIGS. 1B and 1C, respectively. FIG. 3C schematically illustrates an example Brillouin laser 10 in accordance with certain such implementations. In FIG. 3C, as in FIG. 3A, PBS1 can combine the two polarization states from the two diode pump lasers 20a,b before injection into the Brillouin cavity 40 along the two polarization axes via the circulator 42. Also, as in FIG. 3A, PBS2 can receive the two polarization states from the Brillouin cavity 40, which can be combined via PBS3 to generate a beat signal in detector D3, which can be used for temperature control of the Brillouin cavity 40 via the PID circuit.

For simplicity, FIGS. 1A-1C and 3A-3C only show certain implementations with a feedforward scheme of Brillouin laser stabilization without slow PID controls for locking the pump laser frequency such that the Brillouin laser 10 emits at the optimum Stokes shift (as for example discussed with respect to FIG. 1B). In certain other implementations, such slow PID controls can also be included.

To facilitate feedforward locking in certain implementations, the two pump laser outputs can be directed via couplers C2 and C4 to modulators M1 and M2, which can frequency-downshift the pump lasers 20a,b to within a frequency offset of the output of the Brillouin cavity 40 along the two polarization axes. The offset frequency can be in the range from 10 MHz - 1 GHz, but can also be omitted as discussed with respect to FIG. 1C. The two Brillouin outputs and the two down-shifted pump beams can be combined by couplers C3 and C5, respectively, and the resulting beat signals, after RF amplification (e.g., by RF amplifiers 74, 76, respectively) and RF phase shifting via phase shifters Φ₁, φ₂ and control boxes 62, 64, respectively, can be directed back to modulators M3 and M4, respectively, for locking the pump laser frequency such that the Brillouin laser 10 emits at the optimum Stokes shift and for line narrowing as discussed with respect to FIG. 1C. Modulators M5 and M6 can be included to compensate for the frequency shift induced by modulators M3 and M4 and the local oscillator. In conjunction with enclosure of the Brillouin cavity 40 into a vacuum chamber, certain implementations comprise precision temperature control and control of the beat frequency between the two Brillouin polarization modes via the shown PID loop to obtain frequency stability at a level of < 10⁻¹⁴ and even <10⁻¹⁵, resulting in an optical output with a sub Hz linewidth. Moreover, feedforward locking can allow for the use of pump lasers 20a,b comprising relatively low quality pump laser diodes with a linewidth of ≈ 100 kHz - 1 MHz, which can be readily line-narrowed to the tens of Hz level or lower by the feedforward process. The ultra-high stability Brillouin output from the Brillouin laser 10 can, for example, be extracted via output 1 or at other locations in the Brillouin laser 10.

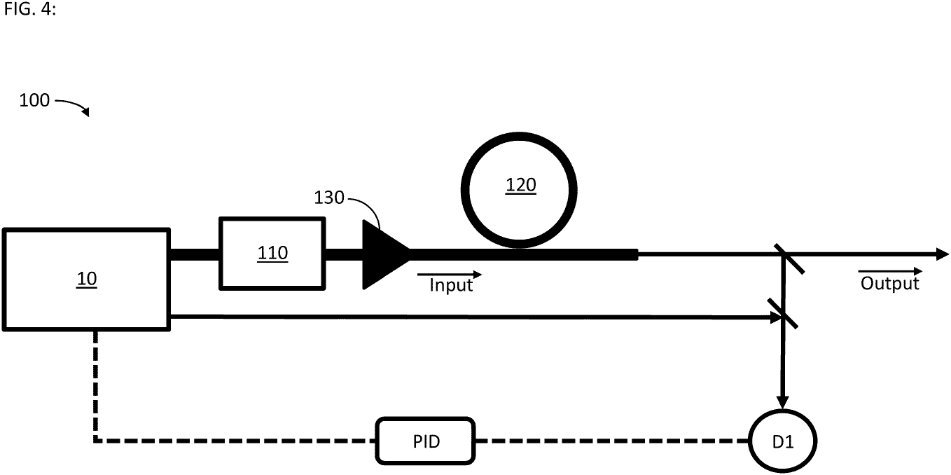

In certain implementations, an ultra-narrow linewidth Brillouin laser 10 can also be used as a pump source for a microresonator based frequency comb 100, an example of which is shown in FIG. 4. Such a source can comprise the Brillouin light source (e.g., comprising a Brillouin laser 10), a modulator 110 or frequency shifter to ensure optimum coupling into the microresonator 120, an amplifier 130 and a nonlinear microresonator 120. The modulator 110 can be a dual-parallel Mach-Zehnder interferometer, an example of which is disclosed in U.S. Pat. Appl. Publ. No. 2021/0294180. The Brillouin laser 10 (e.g., oscillator) can also be configured to operate on two widely separated Brillouin cavity modes simultaneously, an example of which is disclosed in U.S. Pat. Appl. Publ. No. 2018/0180655 and with respect to FIGS. 3A-3C by selection of appropriate pump lasers 20a,b. The frequency separation between the pump lasers 20a,b can be in the range from 1 — 10 THz and even larger.

The microresonator 120 can, for example, be designed to operate in a frequency range from 10 GHz - 1 THz and can be based on materials compatible with a CMOS fabrication process such as silicon nitride (see, e.g., U.S. Pat. Appl. Publ. No. 2021/0294180). The microresonator 120 can then be phase locked to the two Brillouin laser output modes simultaneously via the modulator 110 for phase locking to the first Brillouin output mode and, for example, via an additional actuator for controlling, for example, the pump power to the microresonator 120 via an additional PID loop for phase locking to the second Brillouin output mode. Detector D1 can measure a beat signal between the second Brillouin output mode and an output mode of the microresonator 120. U.S. Pat. Appl. Publ. No. 2021/0294180 discloses techniques for phase locking a microresonator 120 to two cw nodes and for generating very low phase noise microwave or mmwave signals by referencing a microresonator 120 to two ultra-narrow linewidth Brillouin lasers 10 in accordance with certain implementations described herein.

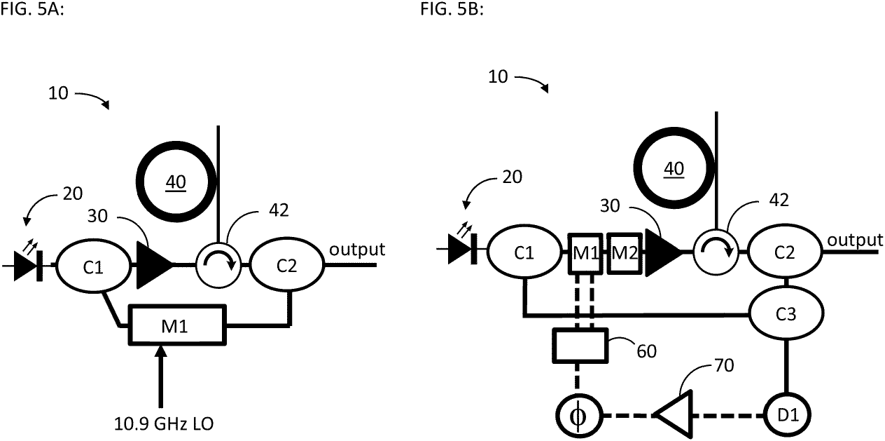

In certain implementations, an ultra-narrow linewidth Brillouin laser 10 can also be highly integrated based on micro-resonators, as shown in FIGS. 5A and 5B. Compact micro-resonators were, for example, disclosed in U.S. Pat. Appl. Publ. No. 2021/0294180. In the example implementations of FIGS. 5A and 5B, the Brillouin cavity 40 is based on a high Q microresonator based on, for example, SiN. Spiral microresonators (see, e.g., U.S. Pat. No. 11,050,214) can also be implemented.

Referring back to FIG. 5A, pump light from the pump source 20 can be coupled into the microresonator of the Brillouin cavity 40 via coupler C1, an optical amplifier 30, and the circulator 42. In certain other implementations based on ultra high Q resonators, the optical amplifier 30 can be omitted. Coupler C2 can extract the frequency down-shifted output from the Brillouin cavity 40 and can direct it back to the pump laser 20 via frequency down-converting modulator M1 for self-injection locking (e.g., as discussed with respect to FIG. 3B). The system output can also be extracted via coupler C2.

In the example implementation of FIG. 5B, pump light from the pump source 20 can be coupled into the microresonator of the Brillouin cavity 40 via coupler C1, an optical amplifier 30, and the circulator 42. In certain other implementations based on ultra high Q resonators, the optical amplifier 30 can be omitted. Coupler C2 can extract the frequency down-shifted output from the Brillouin cavity 40 and can direct it to coupler C3, where it can be combined with the frequency-down shifted pump light. The pump light itself can be appropriately frequency shifted (for example, by controlling the pump current) or offset from the Brillouin gain peak to compensate for the frequency shift by the modulator. Modulator M1 in conjunction with the RF amplifier 70, RF phase shifter Φ, and control box 60 can then simultaneously lock the pump laser frequency such that the Brillouin laser 10 emits at the optimum Stokes shift and line-narrows the pump light (e.g., as discussed with respect to FIGS. 1B and 1C). The beat signal from detector D1 can further be mixed with an RF frequency to reduce the modulation frequency on modulator M1. The system output can also be extracted via coupler C2.

In both of the example implementations of FIGS. 5A and 5B, two pump lasers 20a,b (e.g., two pump laser diodes) can used to excite two orthogonal polarizations inside the Brillouin cavity 40. The output of the Brillouin cavity 40 can then be further directed to a polarization beam splitter to combine the two output polarizations and an additional polarization beat measurement for further temperature stabilization of the oscillator can be included (e.g., as discussed with respect to FIGS. 3A-3C). Such an implementation is not separately shown.

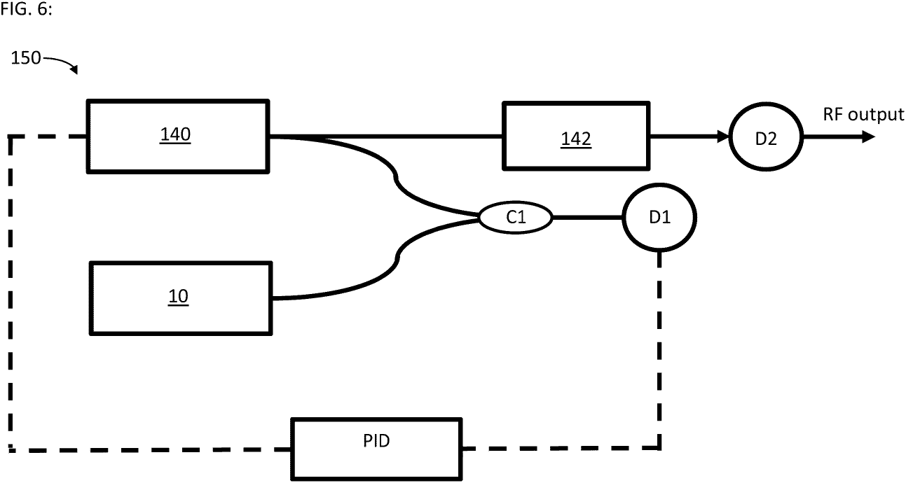

FIG. 6 schematically illustrates an example ultra-narrow linewidth Brillouin laser 10 used in conjunction with a frequency comb 140 as a frequency synthesizer system 150 in accordance with certain implementations described herein. The Brillouin laser 10 can be configured as an ultra-stable frequency reference. The Brillouin laser 10 can be combined with a frequency comb 140 via coupler C1 to generate a beat signal f_{beat} in detector D1. The frequency comb 140 can have its carrier envelope offset frequency f_{ceo} phase locked to a microwave reference and the repetition rate fᵣₑₚ of the frequency comb can be locked to a frequency standard (e.g., for GPS), an optical clock or a Rb clock. The frequency f_{B} of the Brillouin laser 10 can then be calculated as f_{B} = n×fᵣₑₚ + f_{ceo} - f_{beat}. By tracking the values of f_{beat} while tuning the Brillouin laser frequency, the absolute frequency of the Brillouin laser 10 can thus be obtained at every tuning point.

In certain implementation, the system 150 as shown in FIG. 6 can also be readily modified for ultra-low noise microwave generation. By phase locking f_{beat} via repetition rate control in the frequency comb 140, an ultra-stable microwave output can be produced via detection of the frequency comb pulse train with detector D2 via interleaver 142 (see, e.g., U.S. Pat. No. 9,166,361 which also discloses interleavers in accordance with certain implementations described herein).

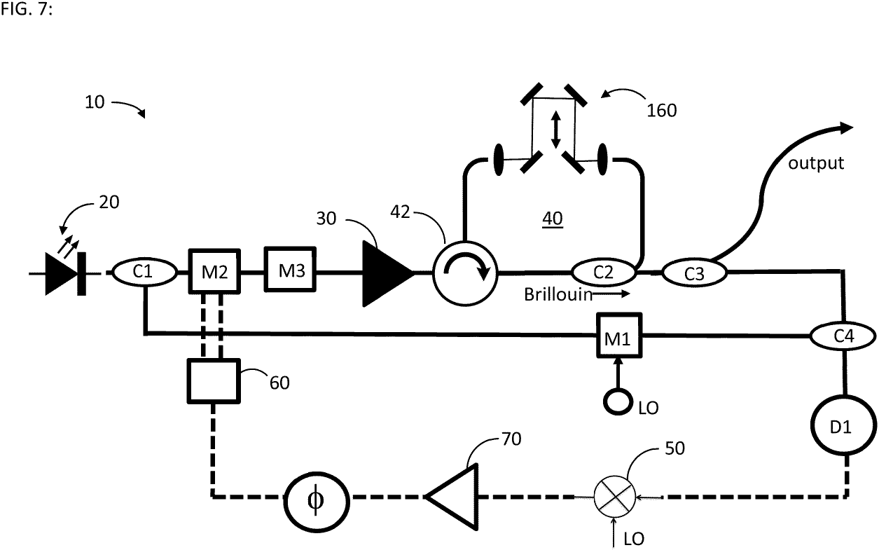

FIG. 7 schematically illustrates an example Brillouin laser 10 configured to be continuously wavelength tunable in accordance with certain implementations described herein. FIG. 7 is substantially similar to FIG. 1C, but includes an added free space delay stage 160 (e.g., comprising a four mirror assembly mounted on a moveable stage). The compact free space delay stage 160 can be implemented that allows for cavity length adjustment (e.g., by 10 cm or more). The mode spacing for a 75 m long fiber cavity is approximately 2.7 MHz, hence by an adjustment of the cavity length by 10 cm, the mode spacing can be changed by around 0.1% or 2.7 kHz. Continuous tuning over a tuning range of 0.1% of the optical frequency is then possible without mode hops. At a central optical frequency of 200 THz, such an adjustment corresponds to a tuning range of 200 GHz without any mode hops by adjustment of the delay stage 160. Even larger tuning ranges are possible with mode hops. The free space delay stage 160 can also be replaced with an all-fiber version (e.g., by coiling a substantial fraction of the fiber onto a PZT drum). Assuming 25 m of the intra-cavity fiber is coiled onto a 40 mm diameter PZT drum, which can have its diameter modulated by around 0.03%, the resonator length can be modulated by around 7.5 mm, which corresponds to a cavity length modulation of around 1×10⁻⁴ and an optical tuning range of 20 GHz without mode hops. In certain implementations, the temperature of the pump laser 20 can be adjusted along with adjustments of the delay stage to reduce (e.g., minimize) any propensity to mode-hops.

To keep track of the frequency of the cw laser in the presence of mode hops, the Brillouin laser 10 can be combined with a frequency comb 140 (see., e.g., FIG. 6). The comb 140 can have its carrier envelope offset frequency locked and its repetition rate locked to an external frequency reference. When the Brillouin laser 10 is tuned, its frequency can be expressed as: f_{B} = n×fᵣₑₚ + f_{ceo} - f_{beat}. If the mode number n, f_{ceo} and fᵣₑₚ of the comb 140 are known, f_{B} can be precisely known. To avoid ambiguities, certain implementations split the comb output in two, and frequency-shift the second part by, for example, a third of the comb repetition rate and then beat that signal with the Brillouin laser 10 using a second photodetector. In certain such implementations, a trackable beat signal is present even when the comb modes and the Brillouin mode are very close in frequency. Splitting a comb output in two to provide a trackable beat signal when using a comb for frequency synthesis was discussed in T. R. Schibli et al., “Phase-locked widely tunable optical single-frequency generator based on a femtosecond comb,” Opt. Lett., vol. 30, 2323 (2005). In certain implementations described herein, in contrast to Schibli et al., the Brillouin laser phase is not locked to the comb 140, only the value of f_{beat} is tracked while the Brillouin laser 10 is tuned. Other methods for continuous frequency tracking can be implemented (see, e.g., E. Benkler et al., “Endless frequency shifting of optical frequency,” Opt. Expr., vol. 21, 5793 (2013)).

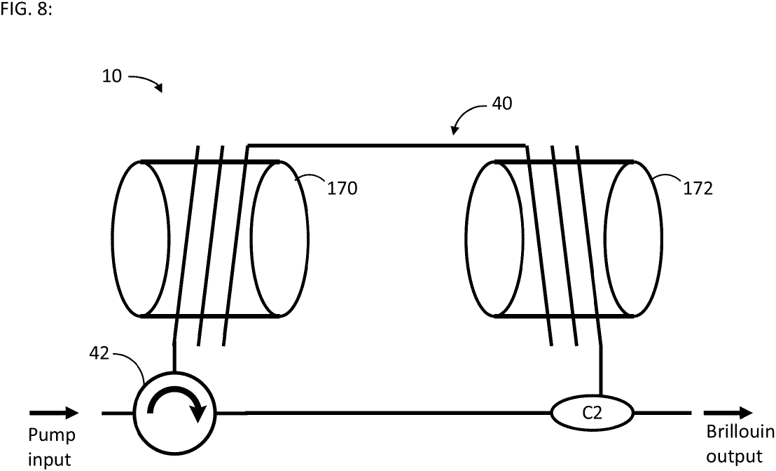

In certain implementation, ultra-narrow linewidth Brillouin laser 10 (e.g., oscillator) with reduced vibration sensitivity can be constructed. As discussed in S. Huang et al., “A Turnkey Optoelectronic Oscillator With Low Acceleration Sensitivity,” Proceedings of the 2000 IEEE/EIA International Frequency Control Symposium and Exhibition (2000), the vibration sensitivity of fiber coils as used in opto-electronic oscillators is largest for vibrations along the fiber axis. The vibration sensitivity can be greatly reduced by splitting the fiber coil in two and winding the two parts of the coil in opposite directions, for example clock-wise and anti-clockwise around the drum or central cylinder. The same principle can also be used to reduce the vibration sensitivity of fiber Brillouin oscillators. FIG. 8 schematically illustrates an example Brillouin laser 10 (e.g., oscillator) with coiling along different directions in accordance with certain implementations described herein. The Brillouin laser 10 can be coiled around two drums 170, 172 and the direction of coiling around the two drums 170, 172 can be reversed between the two drums 170, 172. Each drum 170, 172 can contain approximately the same amount of fiber. The input of the first drum 170 and the output of the second drum 172 can be connected to a circulator 42, which can complete the Brillouin cavity 40. Coupler C2 can be used to couple light from the Brillouin laser 10. The two drums 170, 172 can be rigidly held together to avoid introduction of additional noise.

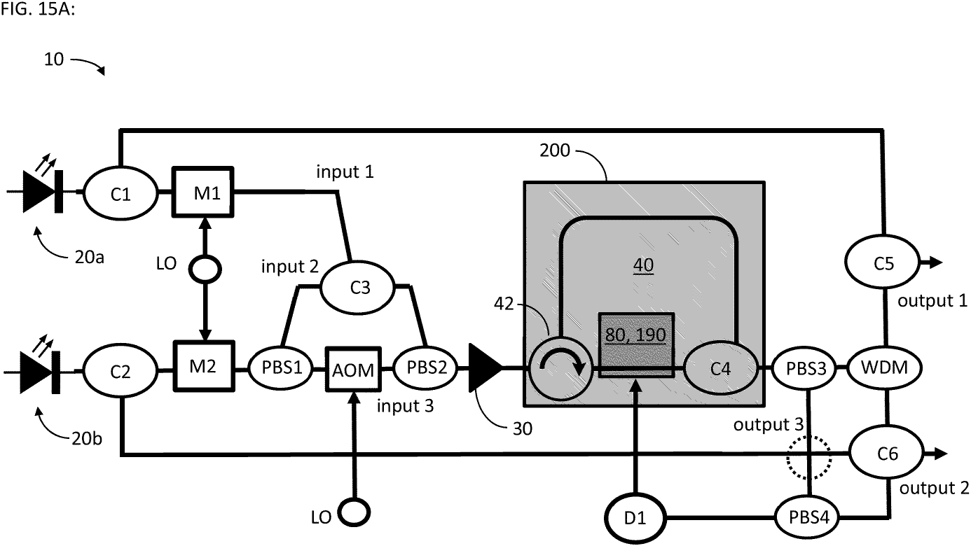

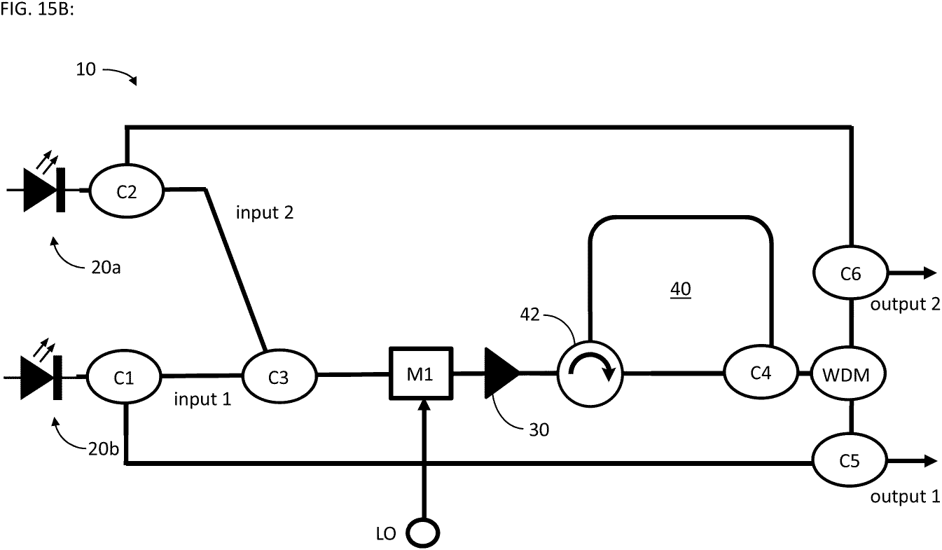

Certain implementations described herein have other benefits, for example, ultra narrow linewidth lasers as described here can be used as frequency references in quantum computing systems, optical clocks, optical communication systems, and/or navigation systems. Equally, the ultra long coherence lengths achievable with the Brillouin fiber lasers of certain implementations described here are particularly useful for fiber based optical time domain reflectometry systems and acoustic sensing applications with very long fiber sensor lengths, exceeding a length of 1 km, 10 km or even 100 km. The Brillouin fiber lasers 10 of certain implementations described here and their very long coherence lengths, their insensitivity to temperature and acceleration fluctuations (e.g., described in the following with respect to FIG. 15A) are generally useful in precision metrology and microwave applications, as well as in precision sensors.

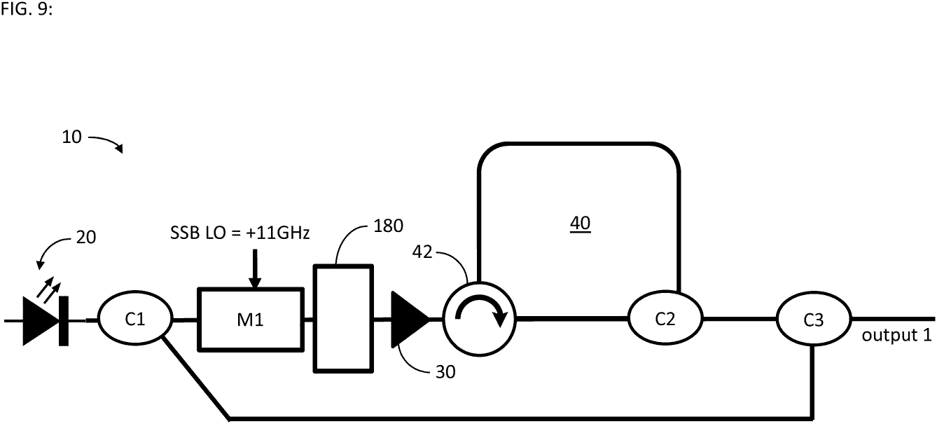

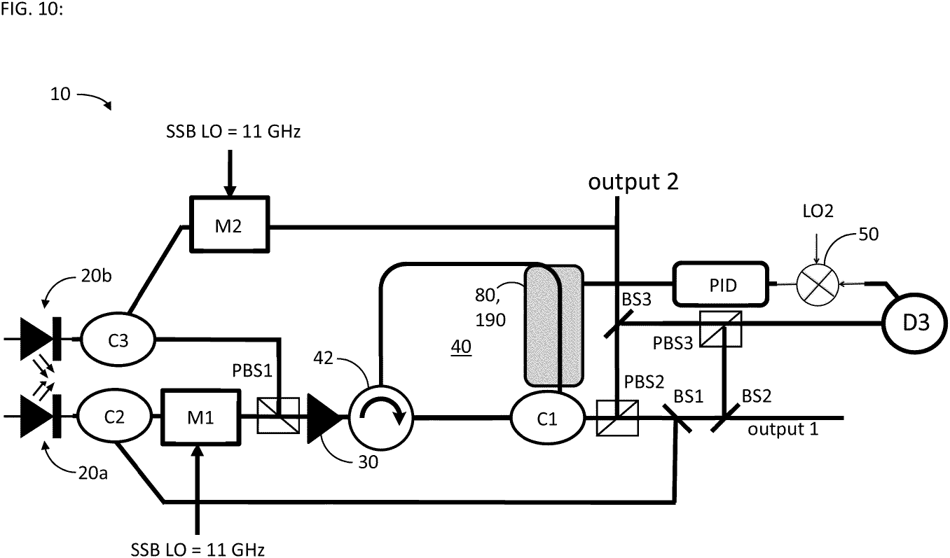

Referring back to FIG. 3B, setting up a Brillouin laser 10 via self-injection of a pump laser 20 in accordance with certain implementations described herein can provide certain benefits. For example, inexpensive diode lasers with a relative broad bandwidth of the order of 1 MHz can be utilized as the pump laser 20 to produce an optical output with a bandwidth of only 1 Hz or less. In certain implementations, to circumvent the frequency difference between Brillouin cavity output and the pump diode laser being around 11 GHz, the diode laser frequency can be frequency up-converted before injection into the Brillouin cavity 40, as shown in FIG. 9. The example Brillouin laser 10 of FIG. 9 is similar to the one shown in FIG. 3B, however, only one pump laser 20 (e.g., pump diode laser) is used and the modulator M1 (e.g., EO modulator) is shifted from the return path to the pump laser 20 to a location upstream of the Brillouin cavity 40. Certain implementations can use a modulator M1 comprising a single-sideband EO modulator to prevent the simultaneous injection of both a frequency upconverted and frequency down-converted frequency node into the Brillouin cavity 40, which can lead to unstable operation. Alternatively, in certain other implementations, the modulator M1 can comprise a standard EO modulator and a narrow band optical filter 180 can be located between the optical amplifier 30 and the EO modulator M1 to attenuate the frequency down-converted EO modulator side-band. An attenuation of the low frequency side band by around a factor of 3 - 10 can be generally sufficient to prevent Brillouin oscillation of that side-band. The Brillouin cavity 40 can then compensate for the frequency up-shift from the EO modulator M1 resulting in substantially the same frequency for both the Brillouin cavity output and the pump laser output.

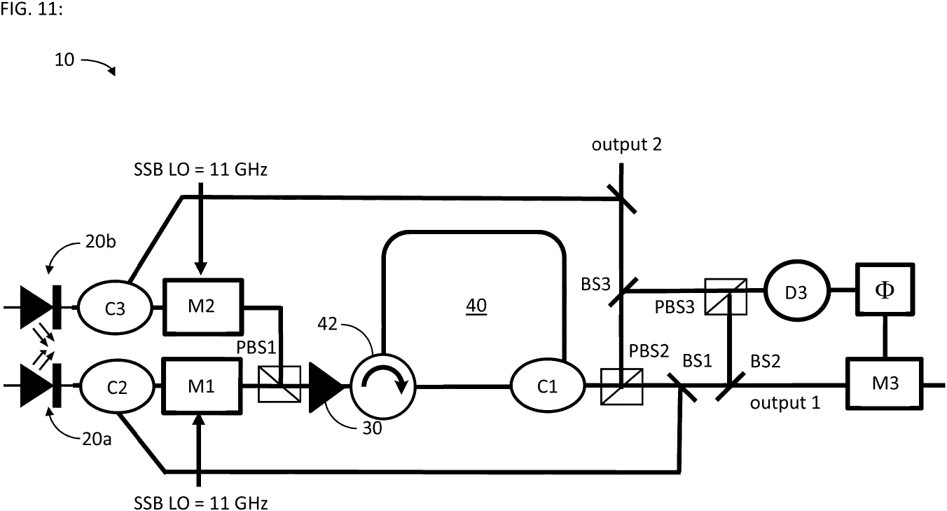

As shown in FIG. 10, in certain implementations, frequency upconversion can also be used with dual polarization operation of a Brillouin cavity 40. FIG. 10 is similar to FIG. 3B, but the EO modulator M1 in the return path to pump laser 20a, as shown in FIG. 3B) has been moved to be upstream of the Brillouin cavity 40. In certain other implementations, one EO modulator M1 up-stream and one EO modulator M2 down-stream of the Brillouin cavity 40 can be used. Just as discussed with respect to FIG. 3B, the temperature of the Brillouin cavity 40 can be sensed via observing the beat between the two polarization outputs of the Brillouin cavity 40 and the cavity temperature can be stabilized (e.g., using a heater 80 in thermal communication with the Brillouin cavity 40) via locking that beat frequency to a reference frequency with a standard feedback circuit. With this approach, sensing (e.g., detection) of the average temperature down to < 10 µK, < 100 nK, < 1 nK and even better can be obtained and the average temperature can be stabilized to within a temperature range less than 10 µK (e.g., less than 100 nK; less than 1 nK).

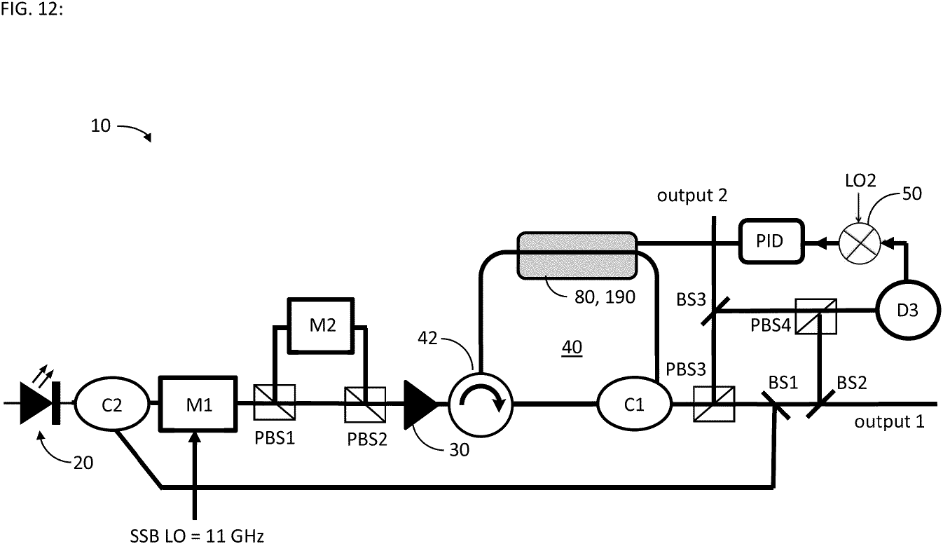

In certain implementations, as shown in FIG. 10, a dual polarization Brillouin laser 10 with intra-cavity actuators (e.g., heater 80; PZT 190) can allow for temperature stabilization or stabilization in view of temperature changes. In certain other implementations, such intra-cavity actuators can be omitted to avoid increased frequency noise resulting from the intra-cavity actuators. For example, as shown in FIG. 11, the beat between the two polarizations can be recorded and a feedforward scheme (as introduced with respect to FIG. 1C) can be used to compensate for the temperature induced frequency noise in one of the outputs of the Brillouin cavity 40. For example, detector D3 can be configured to record the beat between the two polarization outputs of the Brillouin cavity 40, the beat signal can then be amplified and applied via an RF phase shifter Φ to a modulator M3 (for example, an acousto-optic modulator AOM) in the beam path of output 1, to compensate for the temperature induced frequency noise. In certain implementations, the frequency stability of the generated output 1 can further be improved via using the AOM to also compensate for long-term drifts of the Brillouin cavity 40 or by multiplying the measured polarization beat by a numerical factor.

In some implementations, to obtain the highest frequency stability from a Brillouin cavity 40, a single pump laser 20 can be used for dual polarization operation. An example of such an implementation is shown in FIG. 12 in which the pump source 20 (e.g., pump laser diode) is first frequency upconverted via the Brillouin frequency shift via modulator M1 (e.g., a first AOM). Polarization beam splitters PBS1 and PBS2 are then used to generate two pump signals with orthogonal polarizations, where one of the polarizations is frequency shifted via modulator M2 (e.g., a second AOM). The two polarizations are subsequently amplified in a fiber amplifier 30 and injected into a dual polarization Brillouin cavity 40 as already discussed with respect to FIGS. 3A, 3B, and 10. The pump amplitude noise of a single pump diode 20 can be common-mode, which can improve overall frequency stability of the dual polarization Brillouin cavity 40. In principle, the amplitude noise of the pump laser 20 can also be minimized via standard feedback loops. A fraction of the output along the first polarization can be directed via beam splitter BS1 for self-injection to pump laser 20. The modulation frequency of the first and/or second AOM can further be adjusted to lock the difference frequency between (i) the pump signal injected into the second polarization and (ii) the Brillouin output frequency at that second polarization to the Brillouin frequency shift. For example, the difference frequency can be locked to a reference frequency around 10.9 GHz, as already described with respect to FIG. 1A. The difference frequency between the pump laser 20 and the at least one up-converted modulator output frequency can be in a range of 10.5 GHz - 11.5 GHz.

Detection of the beat between the two polarization outputs can be the same as the detection described herein with respect to FIGS. 10 and 11. In certain implementations, the AOM can also be omitted and two polarizations can be coupled into the Brillouin cavity 40 with the same frequency; alternatively, in certain other implementations, two AOMs with nearly compensated frequency shift can be implemented to ensure the two polarizations oscillate at very similar frequencies.

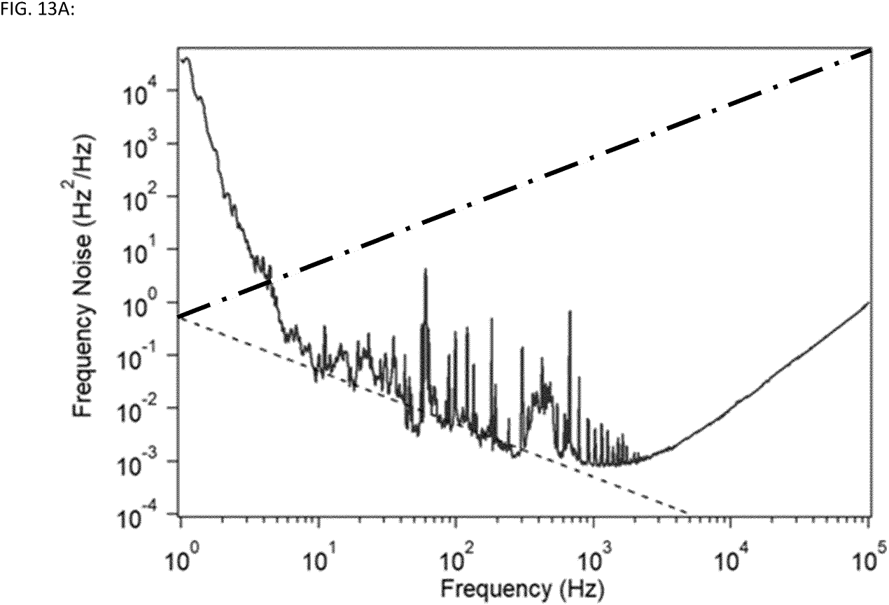

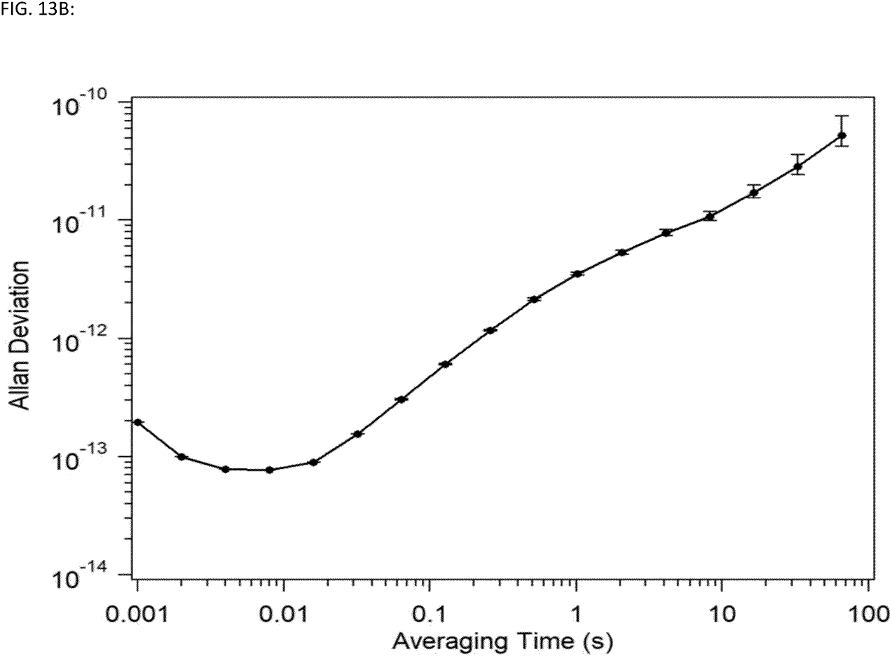

In FIGS. 13A and 13B, the frequency noise and frequency stability obtained with a Brillouin laser 10 as described with respect to FIG. 9 is shown. The dual polarization Brillouin fiber laser 10 had a cavity length of 68 m and a cavity Q of about 2×10⁹, which produced an output power of around 10 mW at 1550 nm. FIG. 13A shows the frequency noise in Hz²/Hz of the beat between the two polarization outputs as a function of sideband frequency. Also shown is the beta separation line (indicated by the dot-dash line); the intersection of the frequency noise plot with the beta separation line occurs at a sideband frequency of around 5 Hz, which corresponds to the frequency bandwidth of the polarization beat. If the frequency noise density as a function of sideband frequency is assumed to be originating from flicker noise with a ⅟f frequency dependence (as indicated by the dashed line), the intersection with the beta separation line is observed at a sideband frequency of less than 5 Hz (e.g., 1 Hz, which corresponds to the intrinsic linewidth of the Brillouin laser output). An intrinsic linewidth of 1 Hz corresponds to a sensitivity to Brillouin cavity temperature of only 20 nK. Assuming the frequency dependence of the output frequency to be 1.65 GHz/°C, the output frequency of the Brillouin laser 10 can be controlled to approximately 33 Hz.

The Allan deviation of the frequency beat between the two polarization outputs is shown in FIG. 13B. Generally, the frequency noise of Brillouin lasers 10 decreases inversely proportional to fiber length. Hence a Brillouin cavity 40 with a length of 200 m can produce an intrinsic linewidth of around 0.3 Hz and a 1 km long Brillouin cavity 40 can reach a linewidth of < 100 mHz. In certain implementations described herein, the frequency stability of the Brillouin output can be of the order < 5×10⁻¹⁴, < 1×10⁻¹⁴, < 3×10⁻¹⁵ and even smaller than 5×10⁻¹⁶ in one second with a fully optimized Brillouin laser 10. This performance is competitive with the best optical references based on bulk cavities previously reported (for example, as described in Y.Y. Jiang et al., “Making optical atomic clocks more stable with 10⁻ ¹⁶-level laser stabilization”, Nature Photonics, vol. 5, pp. 158 - 162 (2011)).

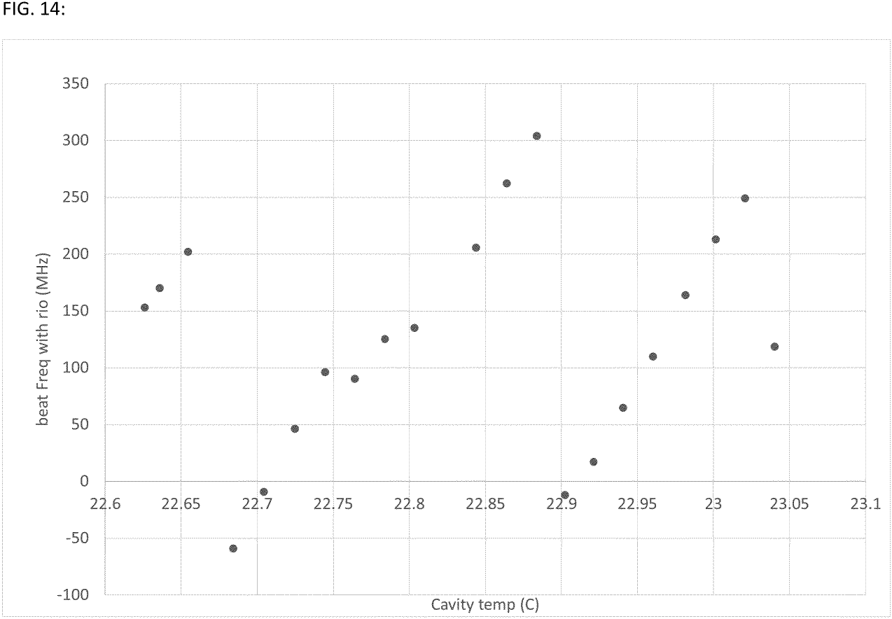

An example measurement of wavelength tuning of a Brillouin laser 10 in accordance with certain implementations described herein is shown in FIG. 14. Here the relative frequency shift of the Brillouin laser output against a stable optical reference is shown as a function of Brillouin cavity temperature. A mode-hop free tuning range from a temperature of 22.7 to 22.9° C. is approximately obtained, corresponding to an optical tuning range of around 350 MHz, about 100 times larger than the free spectral range of the Brillouin laser 10. Mode-hop free tuning and frequency modulation can also be obtained with an intra-cavity fiber stretching device, such as a PZT 190, configured to modulate the Brillouin cavity length. For wavelength tuning in the GHz range, it is useful to tune the pump diode laser temperature in unison with the Brillouin cavity temperature or the Brillouin cavity length.

In certain implementations, the Brillouin laser 10 provides a dual frequency reference (see, e.g., U.S. Pat. Appl. Publ. No. 2018/0180655). An example of a Brillouin laser 10 providing an ultra-low noise dual frequency reference based on self-injection of diode lasers in accordance with certain implementations described herein is shown in FIG. 15A. Such dual frequency references are useful for generation of low noise signals in the mmwave range or generally in the range from 50 GHz - 5 THz. As shown in FIG. 15A, three inputs into the Brillouin cavity 40 can be used, which generate three outputs. In certain implementations, two of the three outputs are in polarizations that are orthogonal to one another and two of the three outputs are in the same polarization as one another.

As shown in FIG. 15A, the example Brillouin laser 10 comprises two pump lasers 20a,b (e.g., two pump diodes). The first pump laser 20a is linked to input 1 and the second pump diode 20b is linked to inputs 2 and 3, with related Brillouin output 1 for the first pump laser 20a and Brillouin outputs 2 and 3 for the second pump laser 20b. Both pump lasers 20a,b are frequency upconverted by two separate modulators M1 and M2 (e.g., single-sideband EO modulators; standard EO modulators with an optical filter as discussed with respect to FIG. 9), inducing a frequency shift for all three inputs. The signal from pump laser 20b is then split via polarization beam splitter PBS1 into two polarizations and travels along two propagation paths, linked to inputs 2 and 3. The signal in the upper path (as shown in FIG. 15A) is linked to input 2. The signal in the lower path (input 3) is frequency shifted via acousto-optic modulator AOM and inputs 2 and 3 along orthogonal polarizations are recombined at polarization beam splitter PBS2. Input 1 is further combined with input 2 via optical coupler C3. For example. coupler C3 can be a wavelength division multiplexing coupler combining inputs 1 and 2 along the same polarization axis.

Down-stream of polarization beam splitter PBS2, all three inputs are amplified via an optical amplifier 30 and injected into the Brillouin cavity 40 via the circulator 42. The output from the Brillouin cavity 40 is extracted via coupler C4. Polarization beam splitter PBS3 then separates output 3 linked to input 3, from outputs 1 and 2, as output 3 is in an orthogonal polarization compared to outputs 1 and 2. Wavelength division multiplexing coupler WDM separates outputs 1 and 2 as they are at different wavelengths and directs them along different optical paths. Couplers C5 and C6 extract a fraction of outputs 1 and 2 and sends those signals back to the respective pump lasers 20a,b for self-injection locking via respective couplers C1 and C2. A fraction of output 2 is further directed via coupler C6 to also interfere with output 2, where both signals are combined via polarization beam splitting coupler PBS4, allowing detection of a beat signal with detector D1. As discussed herein with respect to FIG. 12, the beat signal can be used to control the temperature or the length of the Brillouin cavity 40 via a standard feedback loop and an intra-cavity Brillouin cavity heater 80 and/or a controller of an intra-cavity PZT 190, respectively. In certain implementations, the Brillouin cavity 40 can be within a vacuum chamber 200 configured to stabilize a temperature experienced by the Brillouin cavity 40. The dual frequency output (comprising outputs 1 and 2) from the Brillouin laser 10can be extracted at couplers C5 and C6 and can be directed to an appropriate photodiode such as a UTC diode for generation of a signal in the mmwave or THz domain. The dotted circle in FIG. 15A denotes that there is no cross coupling between crossing optical paths.

The frequency stability of the dual frequency output of a Brillouin cavity 40 as shown in FIG. 15A can be estimated. Assuming a Brillouin cavity 40 as described with respect to FIGS. 13A, 13B, and 14 and assuming the Brillouin cavity 40 is temperature stabilized, the typical frequency drift ν_{d} of the difference frequency Δf between outputs 1 and 2 can be calculated to be approximately ν_{d} = 8.5×10⁻⁶ Δf/°C. For a frequency difference of Δf = 300 GHz, the relative frequency thus drifts by about 2.5 MHz/°C and if the Brillouin cavity 40 is stabilized to 1 mK, the long-term frequency drift reduces to 2.5 kHz. In certain implementations, internal temperature sensing incorporated into the Brillouin laser 10 shown in FIG. 15A can be used to control the temperature of the Brillouin cavity 40 to < 100 nK, providing long-term stabilization of the difference frequency at 300 GHz (extracted from outputs 1 and 2) to around 0.25 Hz or around 1 part in 10⁻¹².

The difference frequency between outputs 2 and 3 (in different polarizations) expressed to first order is not dependent on acceleration or cavity length changes. On the other hand, the difference frequency between outputs 1 and 2 is dependent on acceleration and cavity length changes. To first order, the difference frequency between outputs 1 and 2 depends on cavity length and changes as:

$$Δ \left({v}_{1} - {v}_{2}\right) = \left({v}_{1} - {v}_{2}\right) \frac{δ L}{L} ,$$

where ν₁ - v₂ is the difference frequency of the dual frequency output along a single polarization axis (between outputs 1 and 2), δL is the change in fiber cavity length, L is the cavity fiber length, and Δ(v₁ - v₂) is the δL-induced difference frequency change. For ν₁ - ν₂ = 300 GHz, a fiber cavity length of 100 m, and δL = 10 µm, the difference frequency changes by 30 kHz. Hence, stabilization of the difference frequency (between outputs 1 and 2) to an external microwave reference can stabilize to first order acceleration-induced length changes.

In certain implementations, the difference frequency of two optical nodes (separated widely in frequency space) can be stabilized. For example, outputs 1 and 2 can be sent through an EO modulator, generating side bands from each optical output. The sidebands can thus bridge the large frequency difference between the dual frequency output (between outputs 1 and 2) and the frequency separation of two side-bands separated by a few MHz can then be stabilized by phase locking to an external microwave reference using an intra-cavity PZT via a standard feedback loop. For another example, the beat frequency between the two side-bands can be detected and fed forward to an AOM in the output beam paths of output 1 or output 2 to compensate for acceleration induced frequency changes, similar to certain implementations described herein with respect to FIG. 11, where a feedforward scheme compensates for temperature induced frequency changes. Other methods can also be implemented.

In FIG. 15A, by using three inputs to a Brillouin cavity 40, a unique vibration and temperature insensitive optical reference can be constructed. An intra-cavity heater 80 can be used to stabilize the difference frequency of two Brillouin outputs along different polarization directions (output 2 and 3 in the above example), thereby stabilizing the temperature of the Brillouin cavity 40. An intra-cavity PZT 190 can be used to stabilize the difference frequency of two wavelength outputs along the same polarization (outputs 1 and 2 in the above example), thereby stabilizing any acceleration-induced Brillouin cavity length changes. Alternatively, feedforward schemes can also be implemented to detect temperature or acceleration induced frequency changes and then to compensate those with an appropriate optical modulator.

Hence, certain implementations described herein provide an optical precision frequency reference to first order that is not dependent on thermal and vibration noise (e.g., useful for mobile applications). For example, either outputs 1, 2, 3 can be used as the precision optical frequency reference, since the intra-cavity actuators can compensate for all thermal and vibration noise. For another example, inputs 1, 2, 3 can also be used, since the Brillouin laser 10 is self-injection locked.

The use of three input, three output Brillouin cavities as vibration and temperature independent optical frequency references is not restricted to the use of fiber Brillouin cavities 40. In certain implementations, the same principle can also be applied to other Brillouin lasers 10 that allow operation along two polarization axes, and with three wavelengths, where outputs along orthogonal polarizations are used for precision thermal control and outputs at two widely separated wavelengths along the same polarization are used for acceleration compensation with appropriate intra-cavity actuators or via feedforward schemes. For example, microresonator based optical frequency references that are insensitive to vibration and temperature noise can be constructed in accordance with certain such implementations described herein.

FIG. 15B schematically illustrates an example dual wavelength Brillouin laser 10 in which temperature and vibration immunity is not to be used in accordance with certain implementations described herein. The Brillouin laser 10 of FIG. 15B comprises two pump lasers 20a,b (e.g., two pump diodes) that provide two inputs along the same polarization axis to the Brillouin cavity 40 and generate two outputs. A single modulator M1 frequency upconverts both inputs 1 and 2. Coupler C4 extracts the two outputs (output 1 and output 2) from the Brillouin cavity 40, which are separated by the WDM coupler. Couplers C5 and C6 divert some of the outputs to the pump lasers 20a,b for self-injection and the two outputs are at the same time used for output coupling. The two outputs can be combined on a photodetector (not shown) to generate an output in the mmwave or microwave domain. Alternatively, the modulator M1 can also be between coupler C4 and the WDM coupler to frequency up-convert the outputs from the Brillouin cavity 40 by the Brillouin frequency shift.

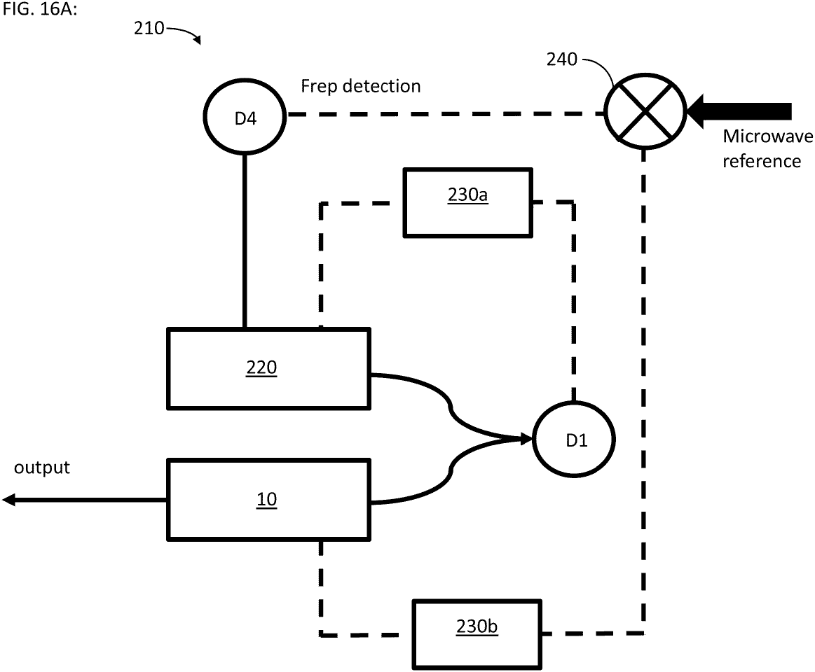

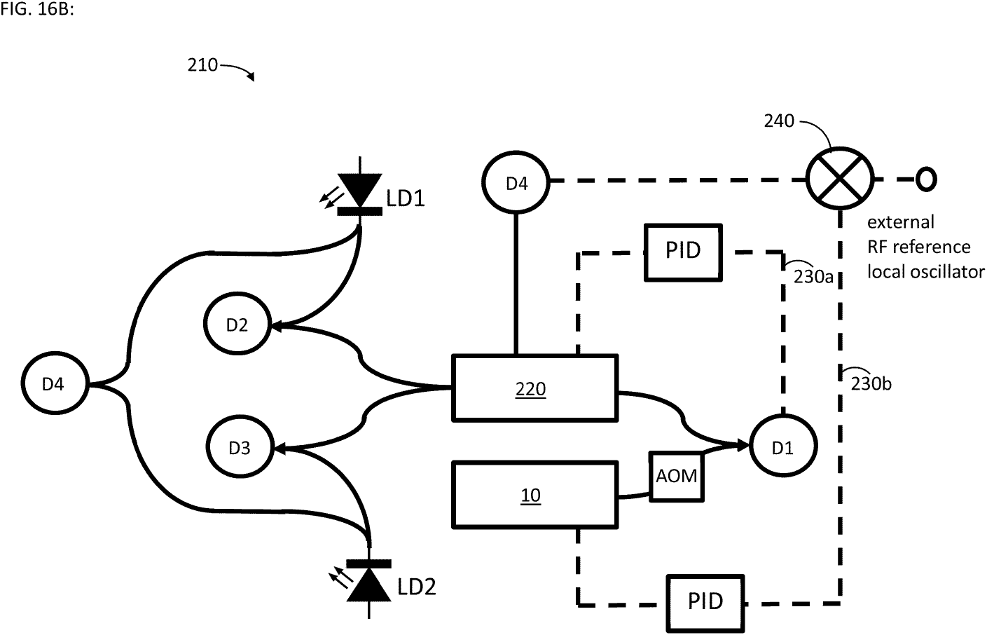

In certain implementations, a highly stable frequency output, oftentimes also the locking of the frequency to an external master frequency reference, such as a GPS reference, or a Rb or optical clock is desired. The frequency of a Brillouin laser can be referenced to an optical clock by observing a beat signal between the Brillouin laser output and said optical clock signal and applying a frequency correction to the optical clock frequency via a modulator. See, e.g., W. Loh et al., “Operation of an optical atomic clock with a Brillouin laser subsystem,” Nature, vol. 588, pp. 244 - 249 (2020). FIG. 16A schematically illustrates a system 210 comprising an ultra-stable Brillouin frequency reference locked to GPS or another microwave reference in accordance with certain implementations described herein. The system 210 comprises a Brillouin laser 10 and frequency comb 220 (with its fceo signal locked also to an external microwave reference), as disclosed herein with regard to FIG. 6, is locked to the output of the Brillouin laser 10 via detection of the beat signal of a comb line with the Brillouin output on detector D1 and a first feedback loop 230a. The repetition rate of the frequency comb 220 is further detected via detector D4 and an error signal obtained via mixing the repetition rate signal with an external microwave reference using a mixer 240. The error signal is then applied to correct the frequency of the Brillouin laser 10 via a second feedback loop 230b. The error signal can also be generated with other means, for example, via frequency counters. In certain such implementations, both long-and short-term frequency stability of the Brillouin output or the repetition rate output of the frequency comb can be obtained.

As described herein with regard to FIG. 6, the system 210 of FIG. 16A transfers the stability of the Brillouin laser 10 in the optical domain to the microwave domain, based on the detection of the frequency comb repetition rate with detector D4. To produce an ultra-low phase noise microwave output, a photodiode with low flicker noise and high saturation current (e.g., UTC photodiode) can be implemented. An interleaver as described with respect to FIG. 6 can also be implemented. If the microwave output frequency does not need to be referenced to another microwave reference, feedback loop 230b can be omitted.

FIG. 16B schematically illustrates a stable dual frequency system 210, with the difference frequency referenced to the Brillouin laser 10 and an external microwave reference in accordance with certain implementations described herein. As shown in FIG. 16B, the system 210 is similar to the system 210 schematically illustrated by FIG. 16A, but two additional diode lasers, LD1 and LD2, are locked to the frequency comb 220 via detectors D2 and D3, which detect a beat frequency of the LD1 or LD2 outputs with next neighbor optical modes generated in the frequency comb 220. Stabilizing those beat frequencies to external microwave references then stabilizes the frequencies of the diode lasers LD1 and LD2. A micro or mmwave signal at the difference frequency between the frequencies of diode lasers LD1 and LD2 can then be obtained by combining the two laser diode outputs on an appropriately selected detector D4, for example a UTC photodiode.

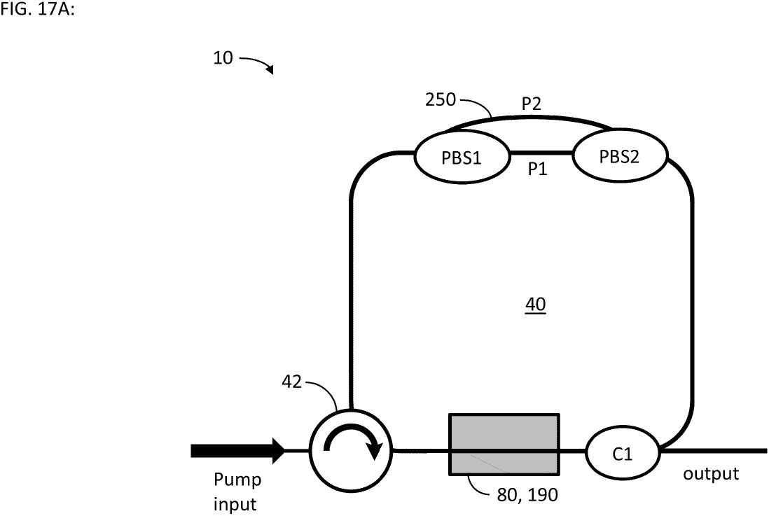

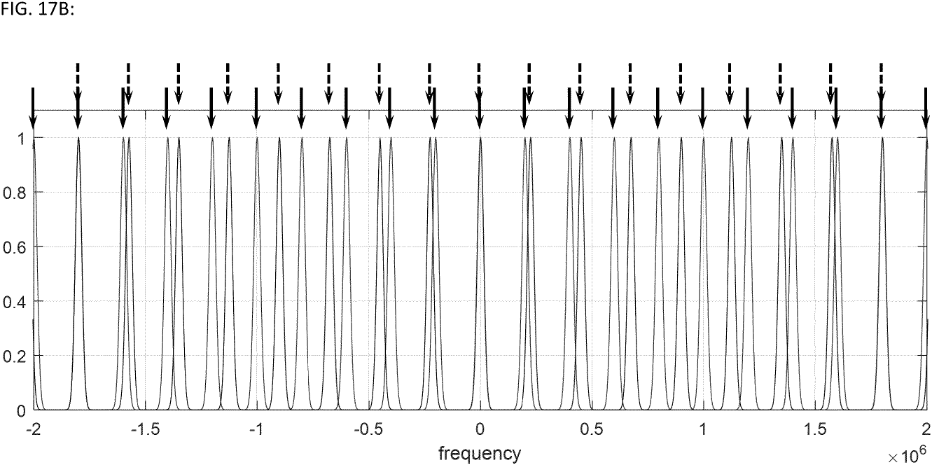

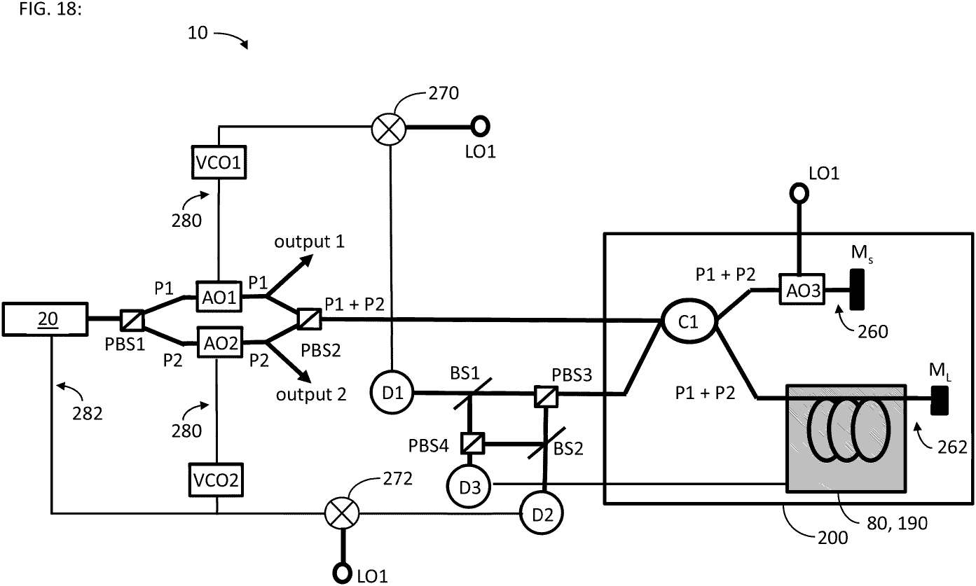

As discussed herein, the frequency noise generated in a Brillouin fiber laser is approximately inversely proportional to fiber length. In certain implementations described herein, the Brillouin laser 10 comprises a cavity length > 150 m (e.g., > 500 m; > 1000 m) to reduce (e.g., minimize) the frequency noise. Because the free spectral range of a 1 km long fiber cavity is only about 200 kHz, about 100 cavity modes can fit into the gain bandwidth of the fiber Brillouin laser 10 of certain implementations described herein and multi-mode operation of the fiber Brillouin laser 10 can occur. To avoid the onset of multi-mode operation, certain implementations comprise a narrow band optical filter in the Brillouin cavity 40. Certain implementations are configured to exploit the Vernier effect by providing different cavity lengths for the two polarizations inside the fiber Brillouin cavity 40. An example implementation of a fiber Brillouin laser 10 with Vernier cavity mode selection is shown in FIG. 17A. The front end of the Brillouin laser 10 up to the circulator 42 is substantially identical to the front end of the Brillouin laser 10 up to the circulator 42 shown in FIG. 12 and is omitted from FIG. 17A. As discussed with respect to FIG. 12, two AOM modulators in series can be used for input coupling of two polarizations with very similar optical frequencies; hence the first AOM can be configured for frequency up-conversion and the second AOM can be configured for frequency down-conversion (or reverse), allowing for precise adjustment of the difference frequency of the two pump wavelengths injected into the Brillouin cavity 40. The back-end from the output of the Brillouin cavity 40 is also substantially identical to the back-end from the output of the Brillouin cavity 40 shown in FIG. 12 and is also omitted from FIG. 17A. The main difference of the Brillouin cavity 40 shown in FIG. 17A as compared to the Brillouin cavity 40 shown in FIG. 12 is that the Brillouin cavity 40 of FIG. 17A comprises different cavity lengths for the two polarization axes P1 and P2. As shown in FIG. 17A, the different cavity lengths are provided by two polarization beam splitters PBS1 and PBS2 and a PM fiber insert 250 configured to extend the cavity length of P2 versus P1. The difference in cavity lengths along the two polarization directions can be between 0.01 - 100% (the natural birefringence of the fiber produces a cavity length difference around 0.01%). In certain implementations, the natural birefringence of the fiber can be used to create two cavities with different cavity lengths and the polarization beam splitters PBS1 and PBS2 can be omitted.

FIG. 17B shows an example plot of the cavity mode spacings for a Brillouin cavity 40 having a first length for light having a first polarization P1 and a second length for light having a second polarization P2 in accordance with certain implementations described herein. The first length of the Brillouin cavity 40 is about 1000 m and produces a cavity mode spacing of ≈ 200 kHz, denoted by the solid arrows. The second length of the Brillouin cavity 40 is about 888.88 m, and produces a cavity mode spacing of ≈ 225 kHz, denoted by the dashed arrows. As shown in FIG. 17B, the two sets of cavity modes can overlap only for a minimum cavity mode separation of (2.25/0.25)×200 kHz = 9*200 kHz = 1.8 MHz. In certain implementations, by selecting a smaller difference between the cavity mode spacings, the frequency separation of the coincidence points can be expanded. For example, selecting the cavity length for light having the second polarization to be 941.2 m with a corresponding second cavity mode spacing of 212.5 kHz produces coincidence points every 18*200 kHz = 3.6 MHz.

Overlapping cavity modes have a higher gain in the Brillouin cavity 40 and can thus preferentially oscillate, reducing the susceptibility to multi-mode operation for very long cavity lengths. Precision temperature control within the Brillouin cavity 40 with such an arrangement can still be introduced via feedback with an intra-cavity heater 80, as also shown in FIG. 12.

The optical Vernier effect can also be used by constructing two coupled Brillouin cavities 40 of different lengths (e.g., using a configuration similar to FIG. 17A), but with the polarization beam splitting couplers PBS1 and PBS2 replaced by polarization-maintaining couplers PM1 and PM2. For example, one cavity length can be 100 m, and the second cavity length can be 1000 m. In order to ensure a similar threshold for Brillouin oscillation along both Brillouin cavities 40, additional attenuators inserted into the Brillouin cavity 40 may be used.

In certain implementations, an optical reference can be constructed via locking of a cw laser to a resonant cavity for ultra-high stability cw output. In certain other implementations, a cw laser can also be locked to an optical delay line (see, e.g., U.S. Pat. Appl. Publ. No. 2018/0180655; EP 2368298). In certain such implementations, thermal drift of the delay line can limit (e.g., reduce) the long-term stability of the optical reference based on a delay line. Dual polarization operation of the delay can allow precise measurements of the temperature of the delay line and can thus maximize the long-term system stability.

FIG. 18 schematically illustrates an example Brillouin laser 10 with a frequency reference based on locking to an optical delay line in accordance with certain implementations described herein. The Brillouin laser 10 of FIG. 18 comprises a pump laser 20 comprising a single frequency cw laser as the input. For example, the cw laser can be a high precision laser with a linewidth < 10 kHz. The cw laser is coupled into the two polarization axes of a polarization maintaining fiber and the two polarization directions are split into two optical paths P1, P2 by polarization beam splitter PBS1. The two AOMs AO1 and AO2 are configured to independently allow for fast frequency modulation of the inputs along the two polarization axes. The outputs of the Brillouin laser 10 can be extracted via additional couplers inserted between the two AOMs and polarization beam splitter PBS2; polarization beam splitter PBS2 is used to recombine the two polarization axes P1 and P2. The combined signals are transmitted to a polarization independent fiber coupler C1 (with a splitting ratio of for example 50/50). The fiber coupler C1 is used to construct an imbalanced fiber Michelson interferometer with a first arm 260 and a second arm 262 longer than the first arm 260 and having a longer delay than does the first arm 260. A polarization independent acousto-optic modulator AO3, driven by a local oscillator LO1, is in the beam path of the short arm 260 to modulate the signals in polarizations P1 and P2 and to facilitate heterodyne beat detection. The long arm 262 can have a length as long as 1 km or even 10 km to provide high frequency stability, whereas the short arm 260 can have a length of around 1 m or even as short as 30 cm. The fiber of the long arm 262 can be mounted on a heater 80 for precision temperature control. The optical components of the imbalanced Michelson interferometer can further be contained within a vacuum chamber 200 to minimize acoustic noise and for maximum temperature stability.

The signals propagating in the long arm 262 and the short arm 260 are reflected at mirrors M_{L} and M_{S}, respectively. After recombination of the signals at coupler C1, the two polarizations are separated by polarization beam splitter PBS3. The heterodyne beat signal between the long arm 262 and the short arm 260 in the first and second polarizations are then detected via detectors D1 and D2 respectively. The phases of the two heterodyne signals can then be detected by mixing them with the same local oscillator LO1 to produce error signals via a first mixer 270 and a second mixer 272 and standard feedback electronics, which are then used for control (e.g., fast) of the input frequencies along the two polarization axes via voltage controlled oscillators VCO1 and VCO2, which modulate the modulation frequencies of acousto-optic modulators AO1 and AO2, respectively.

The error signal for controlling voltage controlled oscillator VCO2 can further be split into a fast component 280 and a slow component 282, where the slow component 282 is used to control the temperature of the pump cw laser 20 and the fast component 280 is used to control voltage controlled oscillator VCO2.

The temperature of the Michelson interferometer can further be detected via generating a beat signal between the two polarizations on detector D3. As shown in FIG. 18, beam splitters BS1 and BS2 can be used to split off a fraction of the signals along the two polarization axes, which are then combined via polarization beam splitter PBS4. The beat signal generated in detector D3 can then be stabilized by feedback electronics, which in turn stabilizes (e.g., slower temperature control than the control of the pump cw laser 20) the temperature of at least the long arm 262 of the Michelson interferometer. Certain implementations provide stabilization of the temperature of the Michelson interferometer to the nK and even sub nK level, which can improve the long-term stability of the pump cw laser 20.

Example, non-limiting experimental data are included herein to illustrate results achievable by various implementations of the systems and methods described herein. All ranges of data and all values within such ranges of data that are shown in the figures or described in the specification are expressly included in this disclosure. The example experiments, experimental data, tables, graphs, plots, figures, and processing and/or operating parameters (e.g., values and/or ranges) described herein are intended to be illustrative of operating conditions of the disclosed systems and methods and are not intended to limit the scope of the operating conditions for various implementations of the methods and systems disclosed herein. Additionally, the experiments, experimental data, calculated data, tables, graphs, plots, figures, and other data disclosed herein demonstrate various regimes in which implementations of the disclosed systems and methods may operate effectively to produce one or more desired results. Such operating regimes and desired results are not limited solely to specific values of operating parameters, conditions, or results shown, for example, in a table, graph, plot, or figure, but also include suitable ranges including or spanning these specific values. Accordingly, the values disclosed herein include the range of values between any of the values listed or shown in the tables, graphs, plots, figures, etc. Additionally, the values disclosed herein include the range of values above or below any of the values listed or shown in the tables, graphs, plots, figures, etc. as might be demonstrated by other values listed or shown in the tables, graphs, plots, figures, etc. Also, although the data disclosed herein may establish one or more effective operating ranges and/or one or more desired results for certain implementations, it is to be understood that not every implementation need be operable in each such operating range or need produce each such desired result. Further, other implementations of the disclosed systems and methods may operate in other operating regimes and/or produce other results than shown and described with reference to the example experiments, experimental data, tables, graphs, plots, figures, and other data herein.

The invention has been described in several non-limiting implementations. It is to be understood that the implementations are not mutually exclusive, and elements described in connection with one implementation may be combined with, rearranged, or eliminated from, other implementations in suitable ways to accomplish desired design objectives. No single feature or group of features is necessary or required for each implementation.

For purposes of summarizing the present invention, certain aspects, advantages and novel features of the present invention are described herein. It is to be understood, however, that not necessarily all such advantages may be achieved in accordance with any particular implementation. Thus, the present invention may be embodied or carried out in a manner that achieves one or more advantages without necessarily achieving other advantages as may be taught or suggested herein.

As used herein any reference to “one implementation” or “some implementations” or “an implementation” means that a particular element, feature, structure, or characteristic described in connection with the implementation is included in at least one implementation. The appearances of the phrase “in one implementation” in various places in the specification are not necessarily all referring to the same implementation. Conditional language used herein, such as, among others, “can,” “could,” “might,” “may,” “e.g.,” and the like, unless specifically stated otherwise, or otherwise understood within the context as used, is generally intended to convey that certain implementations include, while other implementations do not include, certain features, elements and/or steps. In addition, the articles “a” or “an” or “the” as used in this application and the appended claims are to be construed to mean “one or more” or “at least one” unless specified otherwise.

As used herein, the terms “comprises,” “comprising,” “includes,” “including,” “has,” “having” or any other variation thereof, are open-ended terms and intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), or both A and B are true (or present). As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain implementations require at least one of X, at least one of Y, and at least one of Z to each be present.

Thus, while only certain implementations have been specifically described herein, it will be apparent that numerous modifications may be made thereto without departing from the spirit and scope of the invention. Further, acronyms are used merely to enhance the readability of the specification and claims. It should be noted that these acronyms are not intended to lessen the generality of the terms used and they should not be construed to restrict the scope of the claims to the implementations described therein.

What is claimed is:

1. A Brillouin fiber laser providing an ultra-narrow linewidth output, the Brillouin fiber laser comprising:
a single-frequency pump laser,
at least one modulator configured to receive laser light from the pump laser and to produce laser light having at least one up-converted modulator output frequency which is frequency-upconverted with respect to an output frequency of said pump laser, and
a nonlinear cavity configured to receive laser light from said frequency upconverted pump laser and to generate a Brillouin output,
wherein the output from said nonlinear cavity is directed back to the pump laser for self-injection, thereby line narrowing the output of said pump laser.

2. A Brillouin fiber laser according to claim 1, wherein said at least one modulator is located up-stream of said nonlinear cavity.

3. A Brillouin fiber laser according to claim 1, wherein a difference frequency between said pump laser and said at least one up-converted modulator output frequency corresponds to a peak Brillouin gain frequency.

4. A Brillouin fiber laser according to claim 1, wherein a difference frequency between said pump laser and said at least one up-converted modulator output frequency is in a range of 10.5 GHz - 11.5 GHz.

5. A Brillouin fiber laser according to claim 1, further comprising at least one optical amplifier down-stream of said pump laser.

6. A Brillouin fiber laser comprising:
at least one single-frequency pump laser configured to produce two pump signals along two orthogonal polarization directions,
a nonlinear cavity configured to receive laser light from said pump signals and to generate two frequency-downshifted Brillouin outputs along the two orthogonal polarization directions, and
at least one modulator configured to facilitate self-injection of at least one Brillouin output into the at least one pump laser, thereby line narrowing the at least one output of said at least one pump laser.

7. A Brillouin fiber laser according to claim 6, further configured to detect a beat frequency between the two Brillouin outputs along the two orthogonal polarization directions and to detect an average temperature of said nonlinear cavity to temperatures less than 10 µK.

8. A Brillouin fiber laser according to claim 7, further configured to use said polarization beat frequency to stabilize the average temperature of said nonlinear cavity to within a temperature range less than 10 µK.

9. A Brillouin fiber laser according to claim 7, further configured to use said polarization beat frequency to reduce frequency fluctuations of at least one Brillouin cavity output based on a feedforward stabilization scheme.

10. A Brillouin laser comprising:
pump light having at least three different pump frequencies, and
a nonlinear cavity configured to receive said pump light and to generate at least three frequency-downshifted Brillouin laser outputs, where two of the at least three frequency-downshifted Brillouin laser outputs are in polarizations that are orthogonal to one another and two of the at least three frequency-downshifted Brillouin laser outputs are in the same polarization as one another,
wherein the two frequency-downshifted Brillouin laser outputs in the orthogonal polarizations are configured to reduce temperature-induced frequency fluctuations of at least one Brillouin laser output, and the two frequency-downshifted Brillouin laser outputs in the same polarization are configured to reduce acceleration-induced frequency fluctuations of at least one Brillouin laser output.

11. A Brillouin laser according to claim 10, further comprising an optical frequency comb configured to transfer a stability of the at least one Brillouin laser output to the microwave domain, thereby generating an ultra-low phase noise microwave output frequency.

12. A Brillouin fiber laser comprising:
at least one single-frequency pump laser configured to produce two pump signals,
a nonlinear cavity configured to receive laser light from said two pump signals and to generate two frequency-downshifted Brillouin outputs, and
at least one modulator upstream from said nonlinear cavity and configured to facilitate self-injection of at least one of the two Brillouin outputs into the at least one single-frequency pump laser, thereby line narrowing the two pump signals of said at least one pump laser;
said two Brillouin outputs directed to a photodiode for generation of a low noise microwave signal or millimeter wave signal in a range of 50 GHz - 50 THz.

13. A Brillouin laser comprising:
at least one single-frequency pump laser configured to produce outputs;
a nonlinear cavity configured to receive laser light from said at least one pump laser and to generate at least one frequency-downshifted Brillouin output, the nonlinear cavity having a fiber length greater than 150 meters; and
at least one modulator configured to facilitate self-injection of the at least one Brillouin output into the at least one pump laser, thereby line narrowing the outputs of said at least one pump laser.

14. A Brillouin laser according to claim 13, wherein said Brillouin laser output has a frequency output stability corresponding to an Allan deviation of less than 5×10⁻¹⁴ in one second.

15. A Brillouin laser according to claim 13, wherein said Brillouin laser output having a frequency output stability with an optical linewidth less than 5 Hz, as defined with an intersection of a beta separation line with a Brillouin laser frequency noise spectrum as a function of side-band frequency.

16. A Brillouin laser according to claim 13, wherein said Brillouin laser is a component of an optical clock and is configured to provide an optical reference for the optical clock.

17. A Brillouin laser according to claim 13, wherein said Brillouin laser is a component of a quantum computing system and is configured to provide an optical reference for the quantum computing system.

18. A Brillouin laser according to claim 13, wherein said Brillouin laser is a component of a fiber-based optical time domain reflectometry system and is configured to provide a single source for sensing fiber lengths greater than 1 kilometer.

19. A Brillouin laser according to claim 13, wherein said Brillouin laser is a component of an optical communication system or a navigation system and is configured to provide a frequency reference for the optical communication system or the navigation system.

20. An ultra-narrow linewidth laser comprising:
at least one single frequency laser configured to produce an output along two different polarization axes with two different, independently controllable frequencies,
an optical delay line comprising a first optical path and a second optical path, the second optical path longer than the first optical path, said delay line configured to allow simultaneous propagation along two polarization axes, thereby producing two signals along the two polarization axes, said two signals each comprising signals originating from both the first optical path and the second optical path,
at least one optical modulator in at least one of said first and second optical paths,
a coupler configured to receive and combine the two signals from the delay line and to generate interfering signals along each of the two polarization axes,
a polarization beam splitter configured to separate said interfering signals,
two detectors configured to receive said separated interfering signals and to generate two heterodyne beat signals configured to stabilize said two independently controllable frequencies,
a third detector configured to mix the two signals along the two polarization axes and to generate a third beat signal representative of an average temperature of the delay line, and
an optical output coupler configured to produce an ultra-stable optical output derived from said at least one single frequency laser.

21. An ultra-narrow linewidth laser according to claim 20, wherein said third beat signal is configured to stabilize the temperature of the delay line.

22. An ultra-narrow linewidth laser according to claim 20, wherein said third beat signal is configured to improve the stability of said ultra-stable optical output.

23. A device comprising:
a Brillouin laser providing an ultra-narrow linewidth output via a control scheme, the Brillouin laser comprising:
a single frequency pump laser,
at least one actuator configured to frequency modulate said pump laser,
a nonlinear cavity configured to receive laser light from said frequency modulated pump laser and to generate a Brillouin output, the Brillouin output down-converted from said frequency modulated pump laser by a Stokes shift, and
at least one laser controller configured to stabilize said Stokes shift and to reduce a linewidth of said pump laser.

24. The device of claim 23, wherein the at least one laser controller comprises a first proportional integrated differential (PID) feedback loop configured to stabilize said Stokes shift and a second PID feedback loop configured to reduce the linewidth of said pump laser.

25. The device of claim 23, further comprising a microresonator, the Brillouin laser configured to pump the microresonator, said microresonator configured to produce a frequency comb.

26. The device of claim 25, wherein said frequency comb is phase locked to said Brillouin laser which is configured to produce a low phase noise microwave signal.

27. The device of claim 23, wherein said nonlinear cavity comprises a nonlinear fiber cavity.

28. The device of claim 23, wherein said nonlinear cavity comprises a nonlinear microresonator.

29. A device comprising:
a Brillouin laser providing at least one ultra-narrow linewidth output via self-injection, the Brillouin laser comprising:
two single frequency pump lasers,
a nonlinear cavity having two polarization modes configured to receive laser light from said two pump lasers and to generate two Brillouin outputs, the two Brillouin outputs down-converted from said two pump lasers by two separate Stokes shifts, and
a control scheme configured to stabilize a frequency difference between said two Brillouin outputs.

30. The device of claim 29, further comprising a microresonator, the Brillouin laser configured to pump the microresonator, said microresonator configured to produce a frequency comb.

31. The device of claim 30, wherein said frequency comb is phase locked to said Brillouin laser which is configured to produce a low phase noise microwave signal.

32. The device of claim 29, wherein said nonlinear cavity comprises a nonlinear fiber cavity.

33. The device of claim 29, wherein said nonlinear cavity comprises a nonlinear microresonator.
